(19) United States
(12) Patent Application Publication
(10) Pub. No.: US 2026/0353567 A1
(43) Pub. Date: Nov. 5, 2026

(54) IMPEDANCE TUNING AND CROSSTALK REDUCTION FOR HIGH SPEED DIFFERENTIAL VIA

(71) Applicant: Cisco Technology, Inc., San Jose, CA (US)

(72) Inventors: Shadi Ebrahimi Asl, Raleigh, NC (US); Joel Richard Goergen, Soulsbyville, CA (US); Jennifer K. Oliver, San Jose, CA (US)

(21) Appl. No.: 19/197,270

(22) Filed: May 2, 2025

(51) Int. Cl. H05K 3/00; H05K 1/02; H05K 1/11; H05K 3/42

(52) U.S. Cl. CPC H05K 3/0047; H05K 1/0216; H05K 1/116; H05K 3/421; H05K 2201/09509; H05K 2201/0959; H05K 2201/09636; H05K 2203/0207

(57) ABSTRACT

A method and apparatus are provided for creating a double-drilled via on a printed circuit board (PCB). A first cylindrical drill hole is drilled on the PCB having a first diameter and a first central axis. The first cylindrical drill hole is drilled up to a first predetermined depth using a first drill bit. A second cylindrical drill hole is drilled on the PCB, having a second diameter and a second central axis. The second cylindrical drill hole is drilled up to a second predetermined depth using a second drill bit. The second cylindrical drill hole overlaps with the first cylindrical drill hole with the second central axis offset from the first central axis to create the double-drilled via.

### TECHNICAL FIELD

The present disclosure relates to creating vias on printed circuit boards, more specifically to enabling impedance tuning and crosstalk reduction in vias by using a double drilling technique to create the vias.

### BACKGROUND

A printed circuit board (PCB) includes vias to allow electrical connections between different conductive surfaces of the PCB. A PCB has multiple layers and may be thicker than regular PCB and includes long vias that run through all the layers of the PCB to complete a circuit connection. The long vias may become inductive and thereby degrade the performance of an electrical channel due in part to the via causing reflections and lower insertion loss. Generally, non-functional pads are used on signal or ground layers of the vias to aid in adding capacitance to the long vias that are very inductive, thereby controlling and tuning the impedance of the vias to improve the performance of the electrical channel. However, adding non-functional pads on signal layers causes an increase in the crosstalk in any ball grid array (BGA) pin fields on a PCB, as compared to the crosstalk in a BGA pin field of long vias that do not include non-functional pads. Currently, there are limited methods that are known to reduce the added crosstalk in a BGA pin field due to the non-functional pads such as using fewer non-functional pads used in between adjacent via pairs or adding stitching vias in the BGA pin field. However, stitching vias may add cost, as well as additional holes on the planes of the PCB, and may limit flexibility in routing and breakouts in a BGA pin field.

### BRIEF DESCRIPTION OF THE DRAWINGS

FIG. 1 is a schematic diagram depicting a standard drilling process of creating vias on a printed circuit board (PCB), according to an example embodiment.

FIG. 2A is a schematic top view depicting a via created on a PCB using a double drilling technique, according to an example embodiment.

FIG. 2B is a schematic top view depicting a via created on a PCB using a double drilling technique and pads on the via, according to an example embodiment.

FIG. 2C is a schematic perspective view depicting a via created on a PCB using a double drilling technique and pads on the via, according to an example embodiment.

FIG. 3 is a flow chart depicting a method for creating a via on a PCB using a double drilling technique, according to an example embodiment.

FIG. 4A is a schematic diagram depicting a drill hole created on a PCB using step one of a double drilling technique, according to an example embodiment.

FIG. 4B is a schematic diagram depicting a via created on a PCB using step two of a double drilling technique, according to an example embodiment.

FIG. 5 is a schematic diagram depicting a double drilling process of creating vias on a printed circuit board (PCB), according to an example embodiment.

FIG. 6A is a schematic diagram depicting step one of a double drilling process of creating vias on a printed circuit board (PCB), according to an example embodiment.

FIG. 6B is a schematic diagram depicting step two of a double drilling process of creating vias on a printed circuit board (PCB), according to an example embodiment.

FIG. 6C is a schematic diagram depicting step three of a double drilling process of creating vias on a printed circuit board (PCB), according to an example embodiment.

FIG. 6D is a schematic diagram depicting step four of a double drilling process of creating vias on a printed circuit board (PCB), according to an example embodiment.

FIG. 7A is a flow chart depicting a method for creating a via on a PCB using a double drilling technique including plating and filling with epoxy, according to an example embodiment.

FIG. 7B is a diagrammatic representation illustrating an aspect of a double drilling process of creating vias on a PCB, according to an example embodiment.

FIG. 7C is a diagrammatic representation illustrating a top view of the double drilling process of FIG. 7B of creating vias on a PCB, according to an example embodiment.

FIG. 8A is a flow chart depicting a method for creating a via on a PCB using a double drilling technique and filling with epoxy, according to an example embodiment

FIG. 8B is a diagrammatic representation illustrating a first aspect of a double drilling process of creating vias on a printed circuit board (PCB), according to an example embodiment.

FIG. 9 is a diagrammatic representation illustrating a second aspect of a double drilling process of creating vias on a printed circuit board (PCB), according to an example embodiment.

FIG. 10 is a diagrammatic representation illustrating a third aspect of a double drilling process of creating vias on a printed circuit board (PCB), according to an example embodiment.

FIG. 11A is a schematic diagram of a configuration of adjacent vias on a PCB created, using a double drilling process, according to an example embodiment.

FIG. 11B is a schematic diagram of a configuration of adjacent vias on a PCB created, using a double drilling process, according to an example embodiment.

FIG. 11C is a schematic diagram of a configuration of adjacent vias on a PCB created, using a double drilling process, according to an example embodiment.

FIG. 12 is an illustration of time domain reflectometry (TDR) results of simulation of different vias on a PCB, according to an example embodiment.

FIG. 13A is a schematic diagram of adjacent pairs of vias on a PCB created, using a double drilling process, according to an example embodiment.

FIG. 13B is an illustration of crosstalk results of simulation of different type pf adjacent pairs of vias on a PCB, according to an example embodiment.

FIG. 13C is an illustration of crosstalk results of simulation of different types of adjacent pairs of vias on a PCB created using a double drilling process, according to an example embodiment.

FIG. 14A is a schematic diagram of adjacent pairs of vias and ground vias on a PCB created using a double drilling process, according to an example embodiment.

FIG. 14B is an illustration of crosstalk results of simulation of adjacent pairs of vias and ground vias on a PCB, according to an example embodiment.

FIG. 15A is a schematic diagram of pairs of vias facing each other on a PCB created, using a double drilling process, according to an example embodiment.

FIG. 15B is an illustration of crosstalk results of simulation of different types of pairs of vias facing each other on a PCB, according to an example embodiment.

FIG. 15C is an illustration of crosstalk results of simulation of pairs of vias facing each other on a PCB created using a double drilling process, according to an example embodiment.

FIG. 16A is a schematic diagram of pairs of vias facing each other and ground vias on a PCB created using a double drilling process, according to an example embodiment.

FIG. 16B is an illustration of crosstalk results of simulation of pairs of vias facing each other and ground vias on a PCB, according to an example embodiment.

FIG. 17A is a schematic diagram of adjacent pairs of vias and facing pairs of vias impacting a central pair of vias in a ball grid array on a PCB, according to an example embodiment.

FIG. 17B is an illustration of power sum crosstalk (FEXT) results of simulation of the schematic diagram of FIG. 17A, according to an example embodiment.

FIG. 17C is an illustration of power sum crosstalk (NEXT) results of simulation of the schematic diagram of FIG. 17A, according to an example embodiment.

FIG. 18A is a schematic diagram of a first arrangement of adjacent vias on a PCB created, using a double drilling process, according to an example embodiment.

FIG. 18B is a schematic diagram of a second arrangement of adjacent vias on a PCB created, using a double drilling process, according to an example embodiment.

### DETAILED DESCRIPTION

### Overview

According to one embodiment, methods are provided for creating double-drilled vias on a printed circuit board (PCB). A first cylindrical drill hole is drilled on the PCB, the first cylindrical drill hole has a first diameter and a first central axis. The first cylindrical drill hole is drilled up to a first predetermined depth using a first drill bit. The first cylindrical drill hole may be drilled from a top side of the PCB or from a bottom side of the PCB. A second cylindrical drill hole is drilled on the PCB, the second cylindrical drill hole has a second diameter and a second central axis. The second cylindrical drill hole is drilled up to a second predetermined depth using a second drill bit. If the first cylindrical hole is drilled from the top side of the PCB, the second drill hole may be drilled from the bottom side of the PCB or vice versa. The second cylindrical drill hole overlaps with the first cylindrical drill hole such that the second central axis is offset from the first central axis to create the double-drilled via.

### EXAMPLE EMBODIMENTS

Embodiments are presented herein for creating vias on a printed circuit board, and more specifically, to arrangements for creating a via using a double drilling technique to include two overlapping, but separately formed, vertical drill holes having central axis at an offset from each other.

Printed circuit boards (PCBs) are elements used in electronic devices to create electrical connections between components through conductive surface. The complexity of the electronic devices has increased in recent times and there is a rising need to add more components in compact PCBs. PCBs typically include a substrate with multiple layers and double-sided conductive surfaces. Such multi-layered or double-sided PCBs include vias. Vias are holes that are drilled in the PCB and are conductive such that implement electrical connections may be implemented between the different layers of conductive surfaces of the PCB. With the increasing thickness of PCBs, the size, e.g., depth or length, of vias in PCBs is increasing, and as a result, reflections are arising. The reflections affect the controlled impedance of the vias and essentially turn the vias into relatively long inductive vias. Inductive vias degrade the performance of the electrical connections that exist along the vias.

Generally, non-functional pads (NFPs) are added to a long via on a signal layer and/or ground layer of the PCB to add capacitance. NFPs added on the signal layers may control and tune the impedance associated with a long via and may aid in improving the performance of the electrical connections along the vias. However, adding NFPs on the signal layers may lead to the inner surfaces of the vias being relatively close to each other and, hence, cause coupling to occur. Coupling may cause increased crosstalk in a ball grid array (BGA) pin field of the PCB that include vias with NFPs, as compared to the crosstalk generated in a BGA pin field having relatively long inductive vias without NFPs. Crosstalk may have an adverse effect on the overall performance of the PCB.

Embodiments are presented herein for creating a via using a double drilling technique to include two overlapping but separately formed drill holes in the via with the central axis of the two overlapping drill holes at an offset from each other. Such a via may be referred to as a double-drilled via. In the embodiments presented herein, a first drill hole is drilled with a first central axis, followed by drilling a second drill hole with a second central axis. The second central axis is at an offset from the first central axis. That is, the first central axis and the second central axis are not coincident. The double drilling technique may aid with the impedance tuning of relatively long inductive vias while supporting relatively high-speed signals. The double drilling technique may also aid in reducing crosstalk in a BGA pin field generated from using NFPs. The embodiments presented herein may be implemented in signals vias and ground vias to reduce crosstalk generated in BGA pin fields. Thus, the embodiments presented herein provide vias with reduced crosstalk and enable impedance tuning while handling high-speed signals.

It should be noted that references throughout this specification to features, advantages, or similar language herein do not imply that all of the features and advantages that may be realized with the embodiments disclosed herein should be, or are in, any single embodiment. Rather, language referring to the features and advantages is understood to mean that a specific feature, advantage, or characteristic described in connection with an embodiment is included in at least one embodiment. Thus, discussion of the features, advantages, and similar language, throughout this specification may, but do not necessarily, refer to the same embodiment.

Furthermore, the described features, advantages, and characteristics may be combined in any suitable manner in one or more embodiments. One skilled in the relevant art will recognize that the embodiments may be practiced without one or more of the specific features or advantages of a particular embodiment. In other instances, additional features and advantages may be recognized in certain embodiments that may not be present in all embodiments.

These features and advantages will become more fully apparent from the following drawings, description, and appended claims, or may be learned by the practice of embodiments as set forth hereinafter.

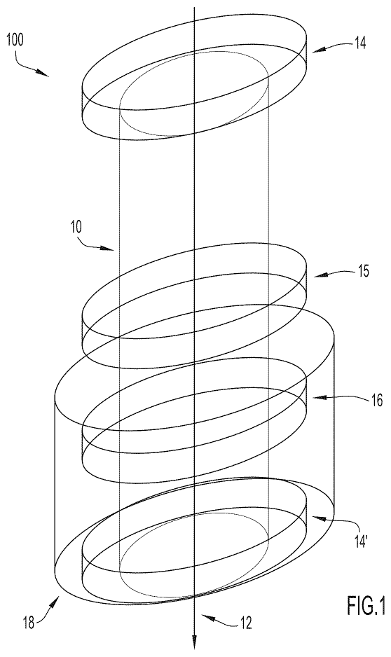

Embodiments will now be described in detail with reference to the Figures. FIG. 1 is a schematic diagram depicting a standard drilling process of a via 100. Drilling a via may typically include drilling a primary hole from a top side or a first side of a PCB, or from a bottom side or second side of the PCB. Drilling from the top side of the PCB may be referred to as top drilling and drilling from the bottom side of the PCB may be referred to as bottom drilling. Consider, in FIG. 1 the schematic diagram of a standard drilling process that drills the via 100 by creating a primary hole 10 by performing top drilling on the PCB. The primary hole 10 is aligned about a central axis 12. The primary hole 10 may be coupled to various pads including a top pad 14, a functional signal pad 15, and a bottom pad 14′. The primary hole 10 of the via 100 may include non-functional pads, for example, NFP 16 around primary hole 10 as shown in FIG. 1. It should be appreciated, however, that the primary hole 10 is not limited to including NFP 16 and may, instead, not include an NFP.

Generally, after the primary hole 10 is drilled, the primary hole 10 is plated using copper plates to implement electrical connections along the primary hole 10. The primary hole 10 drilled through all the layers of the PCB, may result in a plated-through-hole (PTH) and may have a stub at the end of the primary hole 10. For example, primary hole 10 may be drilled as a PTH via, and may be used to provide an electrical connection between the first two layers of the PCB. The remaining unused portion of the drilled primary hole 10 is referred to as a stub of the primary hole 10. The stub generally produces signal integrity issues in high-speed PCBs. To avoid signal integrity issues, the PCB may be flipped after plating to perform back drilling. Back drilling typically involves drilling a secondary hole from a second side of the PCB when a primary hole is drilled from the first side. That is, back drilling involves drilling a secondary hole from a side of a PCB that is an opposite side from which a primary hole is drilled. Additionally, in one embodiment, back drilling includes drilling a hole with a diameter larger than the diameter of the primary hole. In FIG. 1, via 100 includes a back drilled hole 18 having a diameter larger than the diameter of the primary hole 10 but the same central axis 12 as the central axis of the primary hole 10. Back drilled hole 18 may remove the NFP 16 and the bottom pad 14′ of the primary hole 10.

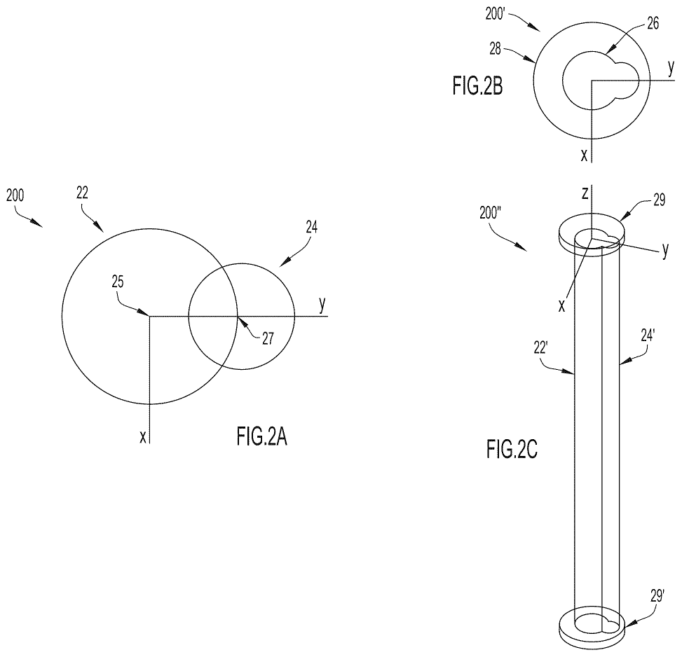

Turning now to FIGS. 2A and 2B, FIG. 2A is a schematic diagram depicting a top view of a via 200 created using the double drilling technique mentioned above, in accordance with an example embodiment. Via 200 includes a primary drill hole 22 (hereinafter, also referred to as a primary hole 22) and a secondary drill hole 24 (hereinafter, also referred to as a secondary hole 24 or side drill hole 24 or side hole 24). It is to be noted that the via 200 in FIG. 2A includes a primary vertical drill hole (top view depicted by primary hole 22) and a secondary vertical drill hole (top view depicted by secondary drill hole 24). FIG. 2A depicts a feature of the double drilling technique, in accordance with an example embodiment. The primary hole 22 and the secondary hole 24 are partially overlapping with the center 25 (or the central axis) of the primary drill hole 22 at an offset from a center 27 (or the central axis) of the secondary drill hole 24. In other words, the distance between the center 25, or the central axis of the primary drill hole 22 and the center 27, or the central axis of the secondary drill hole 24, is such that, the primary drill hole 22 and the secondary drill hole 24 together define a shape of the via 200. It is to be noted that, the exact offset between the centers 25, 27 of the two drill holes 22, 24 depends on a number of factors including, but not limited to including, the material of the PCB, a size of the drill bit used for drilling, and the target impedance of the via.

After a first hole (for example, the secondary drill hole 24) is created through drilling in a PCB, a point may be marked at an offset from the center of the first hole so as to drill the second hole (for example, the primary drill hole 22) in the PCB, resulting in two drill holes that are partially overlapping and are separately formed. Generally, the drill equipment that is used to create the drill holes of the via may use drill bits of various sizes. A size of the drill bit describes the diameters of the two drill holes that are drilled using the drill bits. In the embodiments presented herein, a drill bit of size 5.9 mil may be used to drill the secondary drill hole 24 having a diameter of 5.9 mil. In the embodiments presented herein, a drill bit of size 9.8 mil may be used to drill the primary drill hole 22 having a diameter of 9.8 mil, although it should be appreciated that the sizes of drill bits and, hence, primary drill hole 22 and secondary drill hole 24 may vary widely. The size of drill bits, for example 5.9 mil, 7.9 mil or 9.8 mil refer to the diameters of the drill bits. FIG. 2A shows a via essentially including two drill holes of different sizes with the secondary drill hole 24 having a diameter smaller in size as compared to a diameter of the primary drill hole. In an example embodiment, a diameter of the primary drill hole 22 and a diameter of the secondary drill hole 24 may be the same (either 5.9 mil, 7.9 mil, or 9.8 mil).

FIG. 2B is a schematic diagram depicting a top view of a via 200'. FIG. 2B shows a circumference 26 that indicates an outer surface of the primary hole and the secondary hole of the via 200′ as seen from top. The circumference 26 may indicate the area (or shape) of via 200′ (as seen from the top, or as a top down view) that is formed using a double drilling process, in accordance with the example embodiment. It is to be noted that using a double drilling process may provide an increase in the area of the via, (as compared to a via having a single hole) due to the inclusion of two separate (but overlapping) vertical drill holes 22, 24. FIG. 2B shows a circular feature 28, which may depict the size of the pad for example a top pad used at the top of a via. Generally, a diameter of the feature 28 may be larger than the diameter of the combined size of the primary drill hole 22 and the secondary drill hole 24. In an example embodiment, the size of the circular feature 28 may be approximately 28 mil to incorporate the size of the drill holes 22, 24, for example, 9.8 mil and 5.9 mil. The circular feature 28 may also depict other pads used with a via selected from, but not limited to, mixed pad, functional pads such as guided pad and break out pad, non-functional pads, top pad, and bottom pad.

FIG. 2C is a schematic diagram depicting a perspective view of a via 200'′ via with a primary vertical drill hole 22′ and a secondary vertical drill hole 24′. Via 200″ is coupled with a pad, for example a top pad 29 at the top side and a bottom pad 29′ at the bottom side.

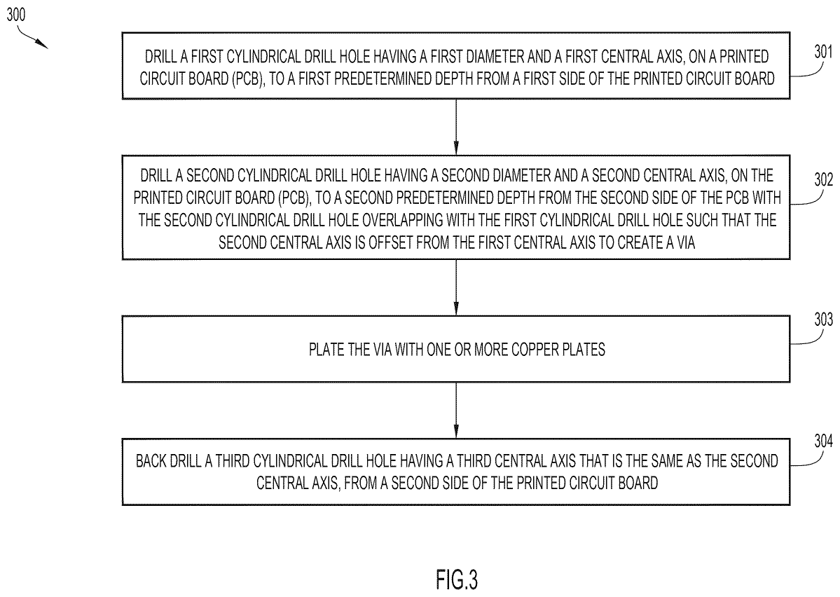

Turning now to FIG. 3, FIG. 3 is a block diagram illustrating an operational flow 300 of forming a via using the double drilling technique, in accordance with an example embodiment. Operational flow 300 begins with operation 301. Operation 301 describes the drilling of a first drill hole, i.e., a first cylindrical drill hole or a first vertical drill hole on a printed circuit board to create a via. It is to be noted that with reference to the via 200 as shown in FIG. 2A, the first drill hole may be the primary hole 22 or the secondary hole 24. Operation 301 describes that drilling the first cylindrical drill hole includes drilling a cylindrical hole of a first diameter about a first central axis. In addition, operation 301 describes that drilling the first cylindrical hole includes drilling a hole up to a first predetermined depth. In other words, a via may be drilled up to a full depth of the PCB as for example, through substantially all the layers of a multi-layer PCB or up to a predetermined depth of the PCB, as for example through one or more layers of the multi-layer PCB, in order to connect the top surface of the PCB to an intermediate layer.

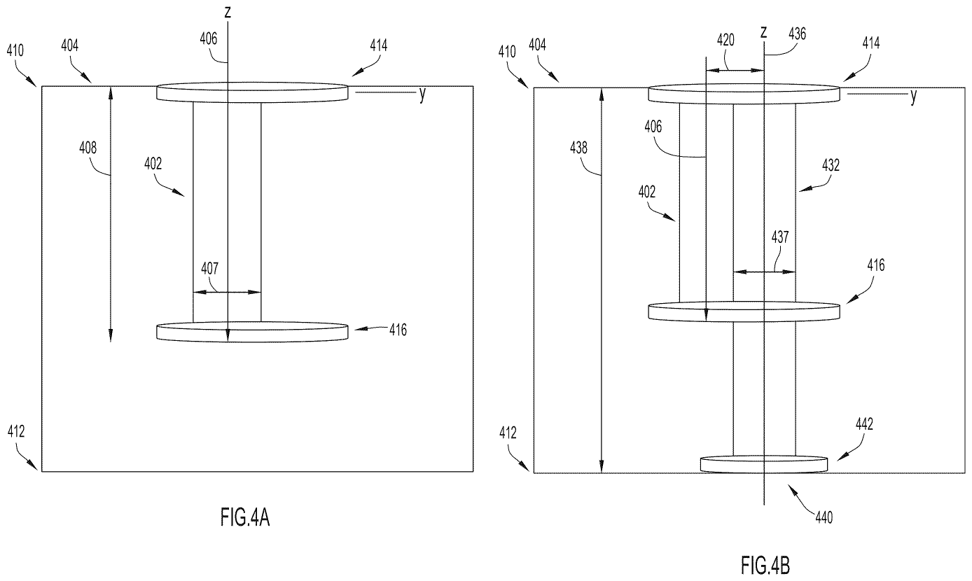

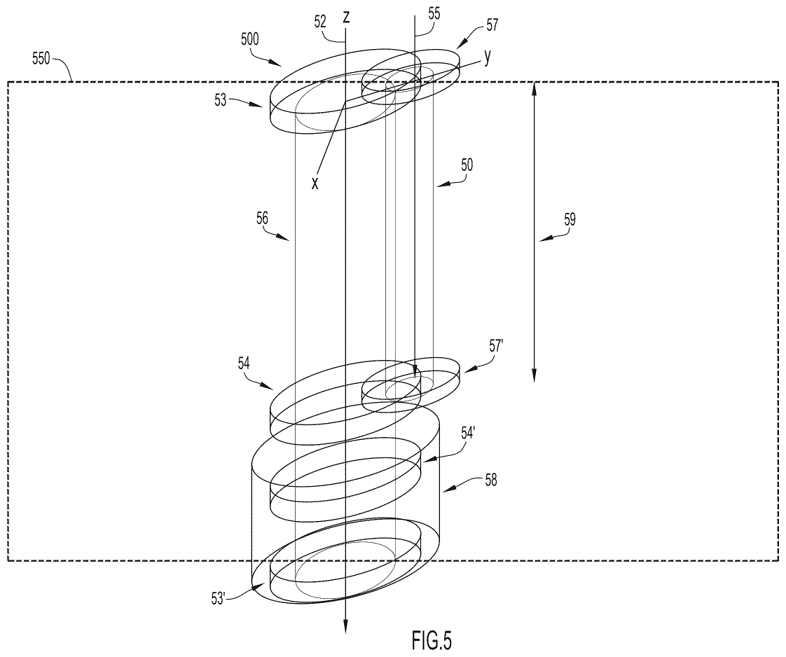

Referring to FIGS. 4A and 4B, schematic diagrams illustrating a process of creating the two drill holes of a via using the double drilling technique, in accordance with an example embodiment. Creating the first cylindrical drill hole through drilling as described in operation 301 may be illustrated by FIG. 4A. FIG. 4A shows a first cylindrical drill hole 402 that is created on a PCB 404 through drilling. The first cylindrical drill hole 402 includes a first central axis 406 and a diameter 407. The drilling of the first cylindrical drill hole 402 in correspondence to the operation 301 is up to a predetermined depth 408. It is to be noted that the predetermined depth 408, as shown in FIG. 4A, is less than the full depth of the PCB board, i.e., the distance between the top surface 410 and the bottom surface 412 of the PCB. In an example embodiment, the predetermined depth 408 may be equal to the distance between the top surface 410 and the bottom surface 412 of the PCB. In an example embodiment illustrated in FIG. 4A, the first cylindrical drill hole 402 may be created by performing top drilling i.e., the first cylindrical drill hole 402 is drilled from the top surface 410 of the PCB, the drill bit moving downside from the top surface 410. It is to be understood that, in an example embodiment, the first cylindrical drill hole 402 may be drilled from the bottom surface 412 of the board by flipping the board to move the drill bit from the bottom surface 412 towards the top surface 410. First cylindrical drill hole 402 may have non-functional pads, including, but not limited to, a top pad or a top pad 414 at the top of the hole 402 and a breakout layer 416 at the end of the cylindrical drill hole 402.

Operation 302 describes the drilling of a second drill hole, i.e., a second cylindrical drill hole or a second vertical drill hole on the PCB to create a via. Operation 302 describes that drilling the second cylindrical drill hole includes drilling a cylindrical hole of a second diameter about a second central axis that is parallel to, and offset from, a first central axis of a first cylindrical drill hole. In addition, operation 302 describes that drilling the second cylindrical hole includes drilling a hole up to a second predetermined depth, for example, a full depth of the PCB i.e., through all the layers of a multi-layer PCB or through one or more layers of the multi-layer PCB (i.e., less than the full depth) in order to connect the top surface of the PCB to an intermediate layer. It is to be noted that the operation 301 and operation 302 describe the double drilling technique, and a result of operations 301 and 302 is that a via is created that includes the first cylindrical drill hole and the second cylindrical drill hole.

The drilling of the second cylindrical hole as described in operation 302 may be illustrated by FIG. 4B. FIG. 4B shows a second cylindrical drill hole 432 that is drilled into a PCB 404. The second cylindrical drill hole 432 includes a second central axis 436, that is parallel to, and offset (at a distance 420) from, a first central axis 406 of a first cylindrical drill hole 402. The second cylindrical drill hole 432 may have a diameter 437, which may be greater than, equal to or smaller than the diameter 407 of the first cylindrical drill hole 402. The drilling of the second cylindrical drill hole 432 in correspondence to the operation 302 is up to a predetermined depth 438. It is to be noted that, in the example embodiment illustrated in FIG. 4B, the predetermined depth 438 is equal to the full depth of the PCB board, i.e., the distance between the top surface 410 and the bottom surface 412 of the PCB. In an example embodiment illustrated in FIG. 4B, the second cylindrical drill hole 432 is formed by performing bottom drilling i.e., the second cylindrical drill hole 432 is drilled from the bottom surface 412 of the PCB. It is to be understood that, in an example embodiment, the second cylindrical drill hole 432 may be drilled from the top surface 410 of the board if the first cylindrical drill hole 402 is drilled from the bottom surface 412 in order to overcome deflection of the drill bit while drilling the second cylindrical drill hole. The second cylindrical drill hole 432 may include a bottom pad 442 at the end of the hole. It is to be noted that in an example embodiment, FIGS. 4A and 4B illustrate the steps of the double drilling technique, and FIG. 4B specifically illustrates a via 440 created from the combination of the first cylindrical drill hole 402 and the second cylindrical drill hole 432.

Moving to the next step of the operational flow 300, operation 303 describes plating the via with a material such as copper, e.g., using copper plates. In order for the via to carry electrical signals and create an electrical connection between various components of the PCB arranged on different layers of a multi-layer PCB, the via is enabled to become conductive in nature by adding one or more copper plates inside the via.

Operation 304 describes the drilling of a third drill hole, i.e., a third cylindrical drill hole or a third vertical drill hole on the PCB, using back drilling. Back drilling may be performed to avoid signal integrity issues when an associated drill hole (for example, the first cylindrical drill hole 402 in FIG. 4A) is drilled up to a depth that is less than a full depth, for example the predetermined depth 408 of the first cylindrical drill hole 402 that extends from the top surface 410 of the PCB 404 to the breakout layer 416, creating a stub in the via that extends from the breakout layer 416 to the bottom surface 412 of the PCB 404. Back drilling may aid in removing the extra plating in the via that is not used, thus reducing signal integrity issues. The PCB 404 may be flipped to face the bottom side, in order to perform back drilling. Operation 304 describes that back drilling includes drilling a cylindrical hole of a larger diameter than the diameter of the second cylindrical drill hole 432, about the second central axis (same as the second cylindrical drill hole 432). In other words, back drilling may include a hole drilled from the bottom surface of a PCB 404 up to the breakout layer 416, removing substantially all of the extra plating in the second cylindrical drill hole 432. It is to be appreciated, the via created using the double drilling process provides electrical and mechanical improvement in a via while minimizing the yield loss.

Turning now to FIG. 5. FIG. 5 is a schematic diagram depicting a via created by the double drilling process described in process flow 300 of FIG. 3, in accordance with an example embodiment. Via 500 includes first cylindrical hole 50 and a second cylindrical hole 56. The first cylindrical hole 50 may be created by performing top drilling or by performing bottom drill on the PCB 550. The first cylindrical hole 50 is created by top drilling on the PCB 550. The first cylindrical hole 50 is aligned about a central axis 55. The first cylindrical hole 50 may include a top pad 57 and a bottom pad 57′. As can be seen from the FIG. 5, the first cylindrical hole 50 is drilled up to a predetermined depth 59, that is, for example, less than the height of the PCB 550. In another example, the predetermined depth 59 of the first cylindrical hole 50 may be approximately the same as the height of the PCB 550.

After the first cylindrical hole 50 is created, the second cylindrical hole 56 is created. In an example embodiment, when the first cylindrical hole 50 is created by performing top drilling on the PCB 550, the second cylindrical hole 56 may be created by performing bottom drilling on the PCB 550, as shown. In another example embodiment, when the first cylindrical hole 50 is created by performing bottom drilling on the PCB 550, the second cylindrical hole 56 may be created by performing top drilling on the PCB 550. While drilling, the second cylindrical hole 56 is aligned about a central axis 52. As will be appreciated, the central axis 52 is at an offset from the central axis 55 of the first cylindrical hole 50. The second cylindrical hole 56 of the via 500 is drilled through the bottom of the PCB 550. The depth of the second cylindrical hole 56 may be a predetermined depth. In an example, the predetermined depth may be less than the length of the PCB 550.

The second cylindrical hole 56 may be coupled to various pads including a top pad 53, a functional signal pad 54, and a bottom pad 53′. The second cylindrical hole 56 of the via 500 may include non-functional pads, for example, NFP 54′ as shown in FIG. 5. It should be appreciated, however, that the second cylindrical hole 56 is not limited to including NFP 54′ and may, instead, not include an NFP.

Generally, after the via 500, including the first cylindrical hole 50 and the second cylindrical hole 56 is created, the via 500 is plated using copper, e.g., one or more copper plates, to implement electrical connections along the via 500. The first cylindrical hole 50 drilled up to a predetermined depth 59, may result in an unused portion i.e., stub at the end of the first cylindrical hole 50. To remove the stub, the PCB 550 may be flipped after plating to perform back drilling. Back drilling in a double drilling process may involve drilling a third hole 58 from a side of a PCB 550 that is the same side from which the second cylindrical hole 56 is drilled. Additionally, in one embodiment, back drilling includes drilling the third hole 58 with a diameter larger than the diameter of the second cylindrical hole 56. In FIG. 5, via 500 includes a back drilled hole 58 having a diameter larger than the diameter of the second cylindrical hole 56 with the same shared central axis 52 as second cylindrical hole 56.

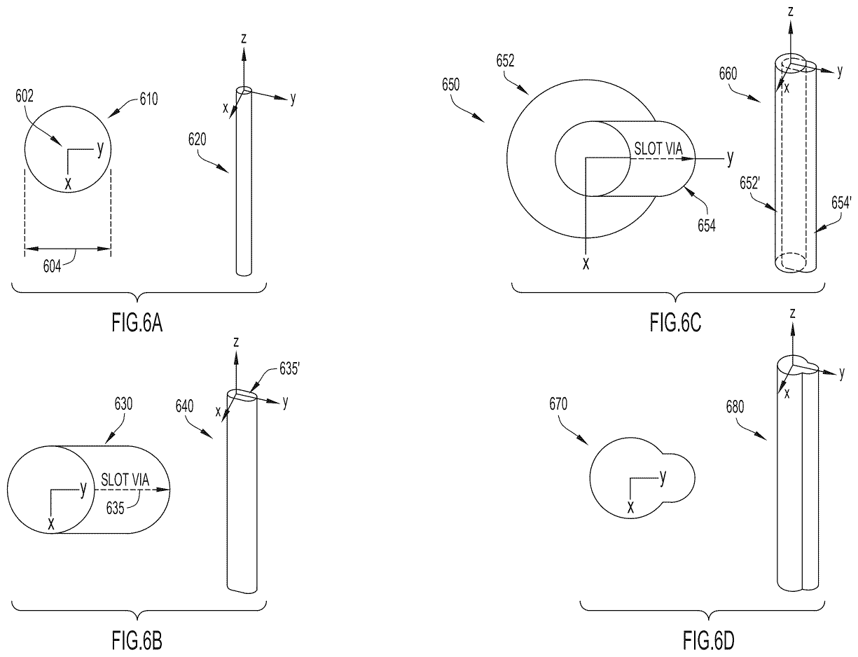

Turning now to FIGS. 6A-6D, FIG. 6A-6D depict steps of a manufacturing process for creating a via using a double drilling process, in accordance to an example embodiment. Manufacturing a via on a PCB may begin by creating a first drill hole. FIG. 6A depicts step one of a process of manufacturing a via which begins by creating a first drill hole. FIG. 6A includes a top view 610 of a first drill hole and a perspective view 620 of the first drill hole. In step one of manufacturing the via, the first drill hole is created by starting from a center point 602 and creating a drill hole i.e., a circular drill hole. Drilling equipment having a drill bit of a predetermined size may be used for creating the circular drill hole of a predetermined diameter 604, for example, a 5.9 mil diameter. For example, top view 610 of the first drill hole indicates that a drill hole of diameter 5.9 mil is created. As discussed above, the size of drill bit for the first drill hole may vary and include other sizes, but not limited to 7.9 mil, 9.8 mil. The circular drill hole is drilled up to a predetermined depth to turn the circular drill hole to a cylindrical drill hole in a PCB. Perspective view 620 of the first drill hole shows the first drill hole as a cylindrical hole.

In one embodiment the cylindrical drill hole, i.e., the first drill hole may effectively be incorporated into a slot via of a predetermined length. FIG. 6B depicts a first drill hole that is used in the creation of a slot via, including top view 630 of the slot via and perspective view 640 of the slot via. The first drill hole, as shown in FIG. 6A, is extended up to a predetermined length 635. Perspective view 640 of the slot via as shown in FIG. 6B shows that the cylindrical drill hole is extended up to the predetermined length 635′ throughout the predetermined depth of the first drill hole.

FIG. 6C indicates the next step in a process of manufacturing a via using a double drilling process which includes creating a second drill hole that overlaps with the first drill hole. FIG. 6C includes top view 650 of the primary hole 652 overlapping with the secondary slot 654. Perspective view 660 of the via includes the second drill hole 652′ and the slot 654′. FIG. 6D depicts another example embodiment of the example embodiment illustrated in FIG. 6C. FIG. 6D depicts an example embodiment in which the first drill slot is not incorporated into a slot via. Top view 670 of the via includes overlapping first drill hole and the second drill hole, perspective view 680 of the via includes overlapping first drill hole and second drill hole, manufactured using the double drilling process.

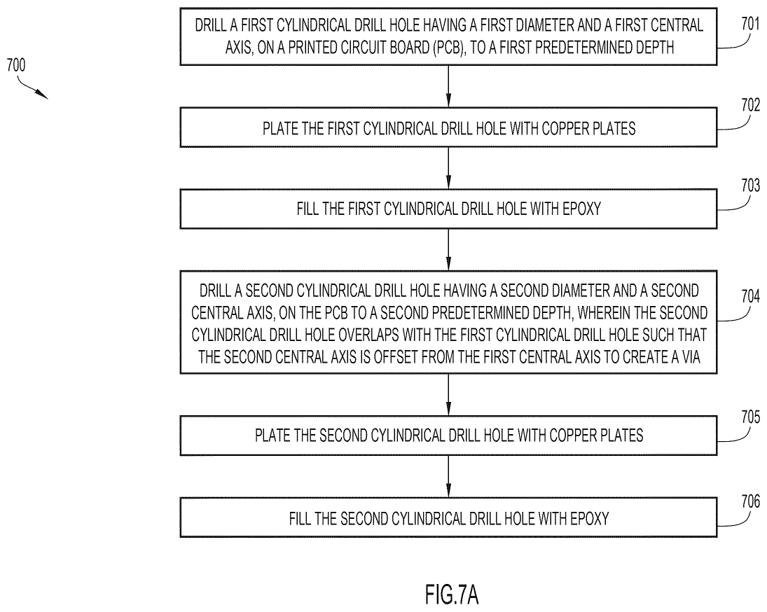

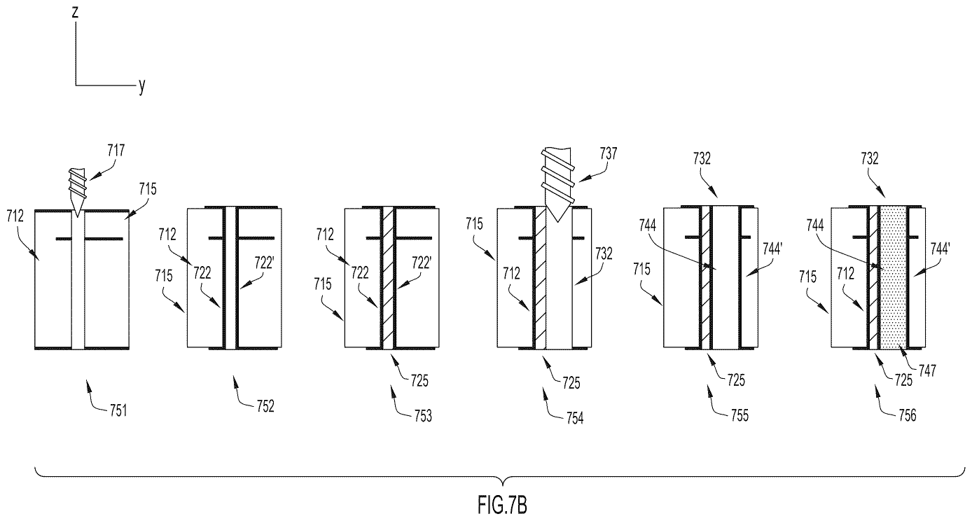

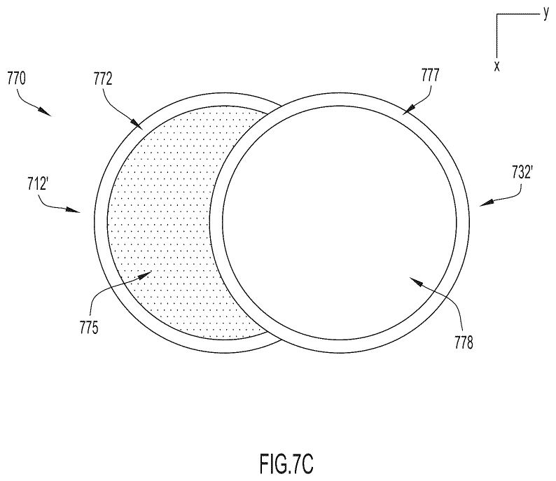

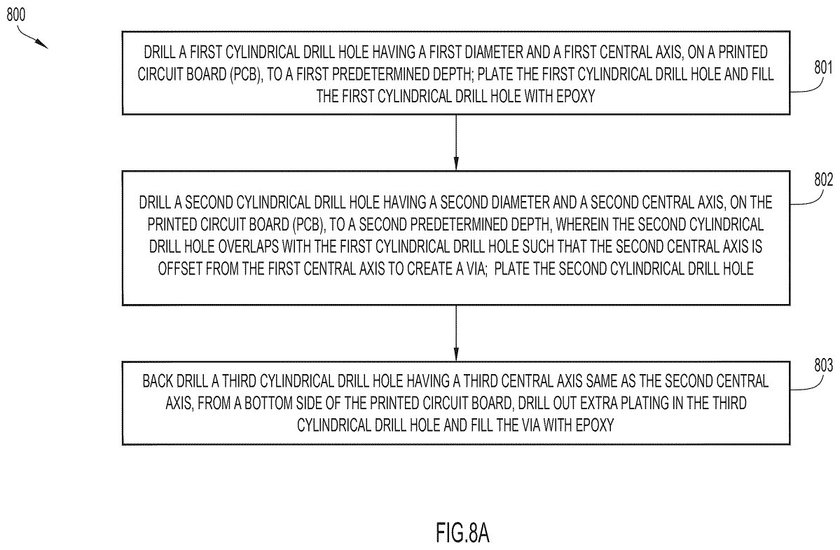

A double drilling process is not limited to being to improve impedance tuning of relatively long inductive vias while supporting relatively high-speed signals. For example, a double drilling process may, in some situations additionally, or alternatively, improve current flow performance. Turning now to FIG. 7A, FIG. 7A is a block diagram illustrating an operational flow 700 of forming a via using a double drilling technique that improves current flow through a via in accordance with an example embodiment. Operational flow 700 begins with operation 701 which describes the drilling of a first drill hole, i.e., a first cylindrical drill hole or a first vertical drill hole on a printed circuit board to create a via. Drilling the first cylindrical drill hole includes drilling a cylindrical hole of a first diameter about a first central axis. In addition, operation 701 describes that drilling the first cylindrical hole includes drilling a hole up to a first predetermined depth. In other words, a via may be drilled up to a full depth of the PCB, e.g., through substantially all of the layers of a multi-layer PCB, or up to a predetermined depth of the PCB, e.g., through one or more layers of the multi-layer PCB, in order to connect the top surface of the PCB to an intermediate layer. The first cylindrical hole may be drilled from a top side or a bottom side of the PCB.

Operation 702 describes a first plating process which includes plating the first cylindrical hole with a suitable material such copper. The inner surface of the first cylindrical hole may be covered with copper. For example, one or more copper plates may be used to cover the inner surface of the first cylindrical hole. Operation 703 describes a first epoxy filling process which involves substantially filling the first cylindrical hole that is plated with copper, with a conductive or a non-conductive material, for example epoxy. The plated cylindrical hole may be filled with a conductive epoxy to allow current to flow through the cylindrical hole. The plated cylindrical hole may be filled with a conductive material or a non-conductive material, for example conductive epoxy or non-conductive epoxy (hereinafter, referred as “epoxy”). Non-conductive epoxy is used to electrically isolate the cylindrical hole.

Operation 704 may describe the drilling of a second drill hole, i.e., a second cylindrical drill hole or a second vertical drill hole on the printed circuit board to create a via. The drilling of the second cylindrical drill hole includes drilling a cylindrical hole of a second diameter about a second central axis. The second central axis is at an offset from the first central axis. That is, the second central axis is parallel to the first central axis but does not coincide with the first central axis. Drilling the second drill hole includes drilling through a portion of the epoxy contained in the first cylindrical hole. In addition, operation 704 describes that drilling the second cylindrical hole includes drilling a hole up to a second predetermined depth, for example, a full depth of the PCB such that the second cylindrical hole is drilled through substantially all the layers of a multi-layer PCB or drilled through one or more layers of the multi-layer PCB in order to connect the top surface of the PCB to an intermediate layer. It should be appreciated that the first cylindrical hole may be drilled from the top side of the printed circuit board and the second cylindrical hole may be drilled from the bottom side of the printed circuit board, or vice versa.

Operation 705 describes a second plating process which includes plating the second cylindrical hole with a suitable material such as copper. For example, one or more copper plates are used for plating, i.e., to cover the inner surface of the second cylindrical hole with copper. The second plating process may include plating at portion of a surface of the epoxy that substantially fills the first cylindrical hole. That is, plating the second cylindrical hole includes plating a portion of the epoxy contained in the first cylindrical hole.

Operation 706 describes the second epoxy filling process which includes the second cylindrical hole that is plated with copper, to be substantially filled with epoxy.

The via created as a result of operations 701 to 706 may include back drilling a third drill hole, i.e., a third cylindrical drill hole or a third vertical drill hole on the printed circuit board to add to the via. The third cylindrical hole may have a larger diameter than the diameter of the primary drill hole, about the second central axis (same as the primary drill hole). It is to be noted that the operations 701 through 706 describe an example embodiment of the double drilling process, and a result of the operations 701 through 706 is that a via is created that includes a first cylindrical drill hole and a second cylindrical drill hole with a plating process after each cylindrical hole is drilled and epoxy filling process after each drilled hole is plated with copper. The via may optionally include a back drilled hole to remove a stub. The back drilled hole may be filled with epoxy and covered with a copper plate.

FIG. 7B depicts an aspect of manufacturing process of a via based on operational flow 700 shown in FIG. 7A. which includes a first plating process, a second plating process, a first epoxy filling process and a second epoxy filling process in accordance with an embodiment. FIG. 7B depicts filling the drill holes of a via with epoxy after individually plating the drill holes with one or more copper plates and includes steps 751 to 756 of a manufacturing process. The steps shown in FIG. 7B are described with respect to diagrammatic cross-sectional representations of a PCB 715. Step 751 indicates creating a first drill hole by drilling a first cylindrical hole 712 into a first side of PCB 715 using a drill bit 717. First cylindrical hole 712 is drilled up to a first predetermined depth. It should be noted that the drill bit 717 may be of a suitable size that correlates to a first predetermined diameter for the first cylindrical hole 712.

Step 752 describes the first plating process which indicates plating the first cylindrical hole 712 with copper plates, for example, copper plates 722 and 722′ cooperate to plate the sides of the first cylindrical hole 712 up to the first predetermined depth. It should be appreciated that copper plates 722 and 722′ may be a substantially continuous copper element around the defining surface of first cylindrical hole 712. In this example, the first predetermined depth is equal to the height of the PCB 715, and the copper plates 722, 722′ cooperate to plate the entire sides of the first cylindrical hole 712.

Step 753 indicates filling the first cylindrical hole 712 with epoxy 725. Epoxy is filled within the inner surface of the first cylindrical hole 712 that is plated with copper plates 722 and 722′.

Step 754 indicates creating a second cylindrical hole 732 overlapping with the first cylindrical hole 712 from the first side of the PCB 715 using a drill bit 737, up to a second predetermined depth. It is appreciated that the central axis of the second cylindrical hole 732 is substantially parallel to, and at an offset from, the central axis of the first cylindrical hole 712. It should be noted that the drill bit 737 may be of a size that correlates to a second predetermined diameter for the second cylindrical hole 732. Copper plate 722′ of the first cylindrical hole 712 may be partially removed when the second cylindrical hole 732 is created through drilling.

Step 755 indicates plating the second cylindrical hole 732 with one or more copper plates, for example, placing copper plates 744 and 744′ along the sides of the second cylindrical hole 732 up to the second predetermined depth. It should be appreciated that copper plates 744 and 744′ may generally be a continuous copper surface,

Step 756 indicates filling the second cylindrical hole 732 with epoxy 747. Epoxy fills the second cylindrical hole 732 that is plated with copper plates 744 and 744′. Steps 751 to 756 result in a via that includes the first cylindrical hole 712 and the second cylindrical hole 732, are plated with copper and filled with epoxy.

FIG. 7C depicts a top view representation of a via 770 created using the manufacturing process of a via that is described in FIG. 7B in accordance with an embodiment. As described with reference to FIG. 7B, via 770 comprises a first cylindrical hole 712′ and a second cylindrical hole 732′. First cylindrical hole 712′ of the via 770 is plated using copper plate(s) 772 and filled with epoxy 775. Second cylindrical hole 732′ of via 770 is plated using copper plate(s) 777 and filled with epoxy 778.

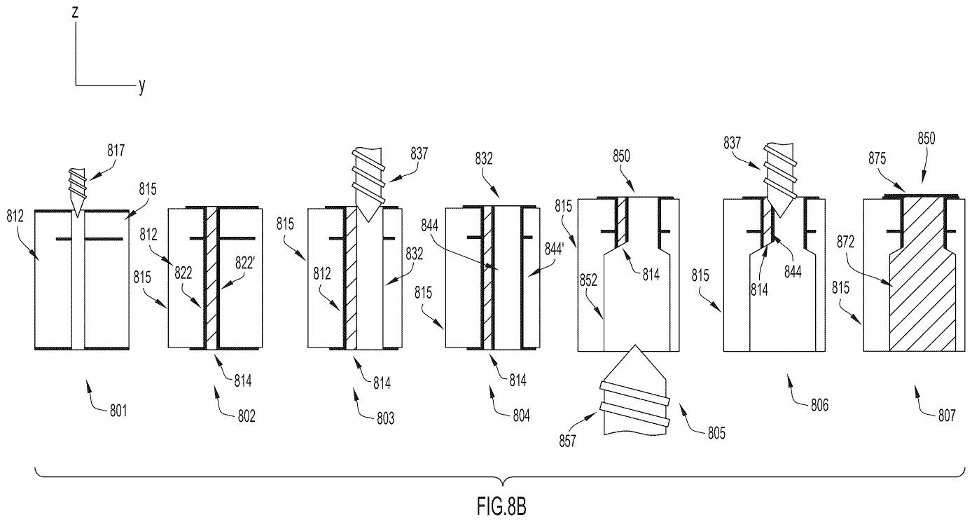

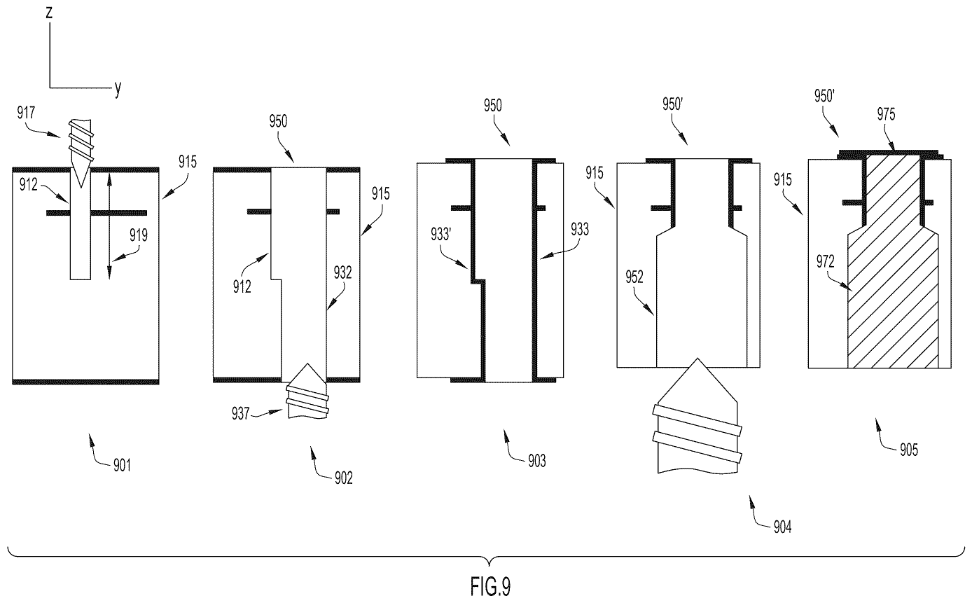

Turning now to FIG. 8A, FIG. 8A is a block diagram illustrating an operational flow 800 of forming a via using the double drilling technique, in accordance with an example embodiment. Operational flow 800 begins with operation 801. Operation 801 describes the drilling of a first drill hole, i.e., a first cylindrical drill hole or a first vertical drill hole on a printed circuit board to create a via. Operation 801 describes that drilling the first cylindrical drill hole includes drilling a cylindrical hole of a first diameter about a first central axis. In addition, operation 801 describes that drilling the first cylindrical hole includes drilling a hole up to a first predetermined depth. In other words, a via may be drilled up to a full depth of the PCB i.e., through all the layers of a multi-layer PCB or up to a predetermined depth of the PCB i.e., through one or more layers of the multi-layer PCB in order to connect the top surface of the PCB to an intermediate layer. Operation 801 describes that the first cylindrical hole is plated with one or more copper plates. Operation 801 includes a feature of substantially filling the plated cylindrical hole with a conductive or a non-conductive material, for example epoxy. The plated cylindrical hole may be filled with a conductive epoxy to allow current to flow through the cylindrical hole. The plated cylindrical hole may be filled with a non-conductive epoxy to electrically isolate the cylindrical hole.

Operation 802 may describe the drilling of a second drill hole, i.e., a second cylindrical drill hole or a second vertical drill hole on the printed circuit board to create a via. Operation 802 describes that drilling of the second cylindrical drill hole includes drilling a cylindrical hole of a second diameter about the second central axis. Operation 802 describes that the second central axis is at an offset from the first central axis. In addition, operation 802 describes that drilling the second cylindrical hole includes drilling a hole up to a second predetermined depth, for example, a full depth of the PCB i.e., through all the layers of a multi-layer PCB or through one or more layers of the multi-layer PCB in order to connect the top surface of the PCB to an intermediate layer. Operation 802 describes that the second cylindrical hole is plated with copper, for example with one or more copper plates.

Operation 803 may describe the drilling of a third drill hole, i.e., a third cylindrical drill hole or a third vertical drill hole on the printed circuit board through back drilling. Back drilling may aid in removing the extra plating and the filled epoxy in the stub of the via that is not used. The PCB may be flipped facing the bottom side, to perform back drilling. Operation 803 describes that back drilling includes drilling a cylindrical hole of a larger diameter than the diameter of the primary drill hole, about the second central axis (same as the primary drill hole). In other words, back drilling may include a hole drilled from the bottom surface of a PCB up to the point at which secondary hole is drilled, while removing extra plating and epoxy filling in the via. It is to be noted that the operations 801 through 803 describe an example embodiment of the double drilling process, and a result of the operations 801 through 803 is that a via is created that includes a first cylindrical drill hole, a second cylindrical drill hole, and a back drilled third cylindrical hole. The via created may be covered with copper, for example one or more copper plates. Operation 803 describes filling the plated via with a conductive material, for example epoxy.

Turning to FIGS. 8B-10, aspects of example embodiments discussed in operational flow 800 will be described. FIG. 8B depicts a first aspect of manufacturing process of a via which includes filling a first drill hole and the via with epoxy after individually plating the first drill hole and the via with one or more copper plates. FIG. 8B includes operations (steps) 801 to 807 of a manufacturing process. Operation 801 indicates creating a first drill hole by drilling a first cylindrical hole 812 into a first side of a PCB 815 using a drill bit 817, up to a first predetermined depth. It should be noted that the drill bit 817 may be of a size that correlates to a first predetermined diameter for the first cylindrical hole 812. Operation 802 indicates plating the first cylindrical hole 812 with copper plates, for example, copper plates 822 and 822′ cooperate to plate the sides of the first cylindrical hole 812 up to the first predetermined depth. In this example, the first predetermined depth is equal to the height of the PCB 815, and the copper plates 822, 822′ cooperate to plate the entire sides of the first cylindrical hole 812. Operation 802 also indicates filling the first cylindrical hole 812 with epoxy 814 (indicated by lines).

Operation 803 indicates creating a second cylindrical hole 832 overlapping with the first cylindrical hole 812 from the first side of the PCB 815 using a drill bit 837, up to a second predetermined depth. It is appreciated that the central axis of the second cylindrical hole 832 is at an offset from the central axis of the first cylindrical hole 812. It should be noted that the drill bit 837 may be of a size that correlates to a second predetermined diameter for the second cylindrical hole 832. Copper plate 822′ of the first cylindrical hole 812 may be removed while creating the second cylindrical hole 832 through drilling. Step 804 indicates plating the second cylindrical hole 832 with copper plates, for example, placing copper plates 844 and 844′ along the sides of the second cylindrical hole 832 up to the second predetermined depth. Step 805 indicates the process of back drilling from a second side of the PCB 815. Back drilling includes creating a third cylindrical hole 852 using a drill bit 857, while removing the excess plating of the first cylindrical hole 812 and the second cylindrical hole 832, in addition to excess of epoxy 814 filled into the first cylindrical hole 812. Drill bit 857 may be larger in size than drill bit 817 and drill bit 837. Step 805 may include addressing a depth of the first cylindrical hole 812 and the second cylindrical hole 832 that is incorporated by the back drilled third cylindrical hole 852.

Step 805 may result in the via 850 including the first cylindrical hole 812, the second cylindrical hole 832, and the third cylindrical hole 852. Step 806 indicates drilling out copper plate 844 of the second cylindrical hole 832 (that is in contact with epoxy 814 filled into the first cylindrical hole 812) from the first side of the PCB 815. Drill bit 837 may be used in step 806. Step 807 indicates filling the via 850 with epoxy 872 (indicated by lines). Step 807 may also indicate adding copper plate 875 on top of the via 850 filled with epoxy 872.

FIG. 9 depicts a second aspect of a manufacturing process of a via which includes creating a first drill hole and the second drill hole from different sides of the PCB and, after the via is created, filling the via with epoxy in accordance with an embodiment. FIG. 9 includes steps 901 to 905 of a manufacturing process. Step 901 indicates creating a first drill hole by drilling a first cylindrical hole 912 into a first side of a PCB 915 using a drill bit 917. It can be noted that the drill bit 917 may be of a size that correlates to a first predetermined diameter for the first cylindrical hole 912. The first cylindrical hole 912 may be drilled up to a first predetermined depth 919 into the PCB 915.

Step 902 indicates creating a second drill hole by drilling a second cylindrical hole 932 that overlaps with the first cylindrical hole 912 from a second side of the PCB 915 using a drill bit 937, up to a second predetermined depth. It is appreciated that the central axis of the second cylindrical hole 932 is at an offset from the central axis of the first cylindrical hole 912. It should be noted that the drill bit 937 may be of a size that correlates to a second predetermined diameter for the second cylindrical hole 932. In one example embodiment of the second aspect, the second cylindrical hole 932 may be created from the first side of the PCB 915 if the first cylindrical hole 912 is created from the second side of the PCB 915. A via 950 is created with the overlapped first cylindrical hole 912 and second cylindrical hole 932 drilled into the PCB 915.

Step 903 indicates plating the via 950 with copper plates, for example, copper plates 933 and 933′ cooperate to plate the entire sides of the via 950. Plating a via 950 typically includes placing copper plates 933 and 933′ along the edges of the via 950. Step 904 indicates the process of back drilling from a second side (for example, the same side through which the second cylindrical hole 932 was created in step 902) of the PCB 915. Back drilling includes creating the third cylindrical hole 952, while removing the excess plating of the via 950 and modifying the via 950 such that via 950′ is created to include the back drilled hole 952. Step 904 may include addressing a depth of the via that is incorporated by the back drilled third cylindrical hole 952. Step 905 indicates filling the via 950′ with epoxy 972 and adding copper plate 975 on top of the via 950′ after via 950′ is filled with epoxy 972.

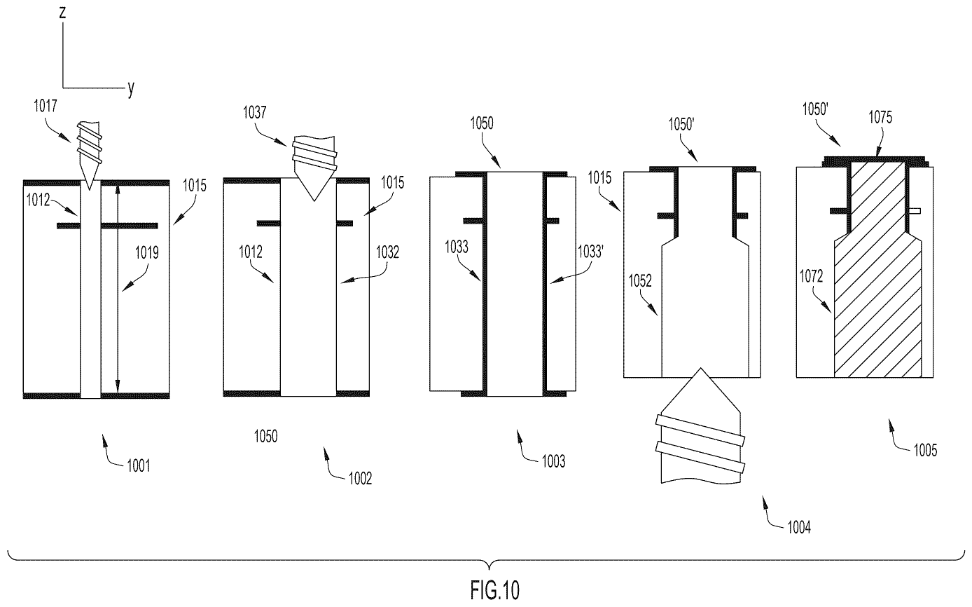

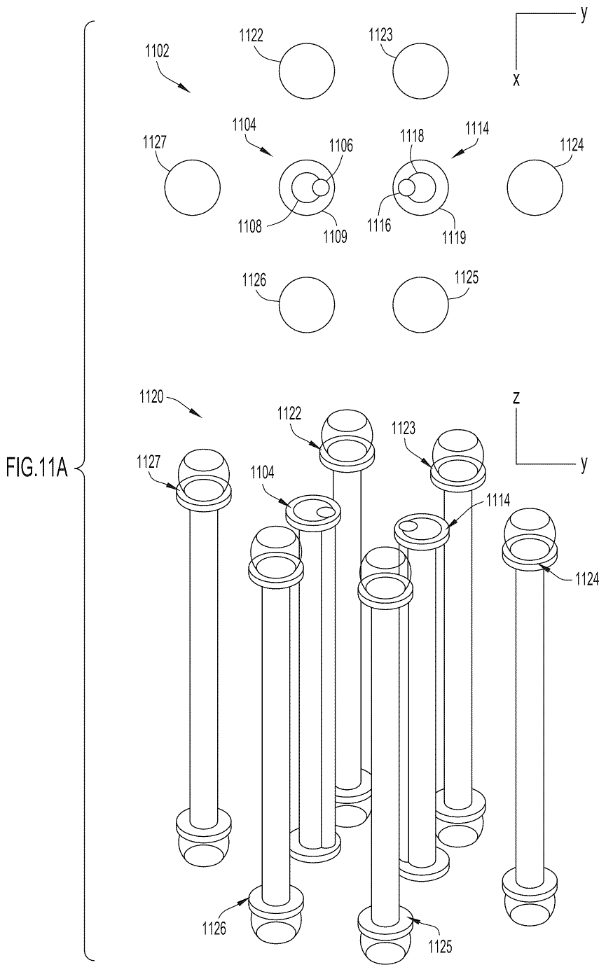

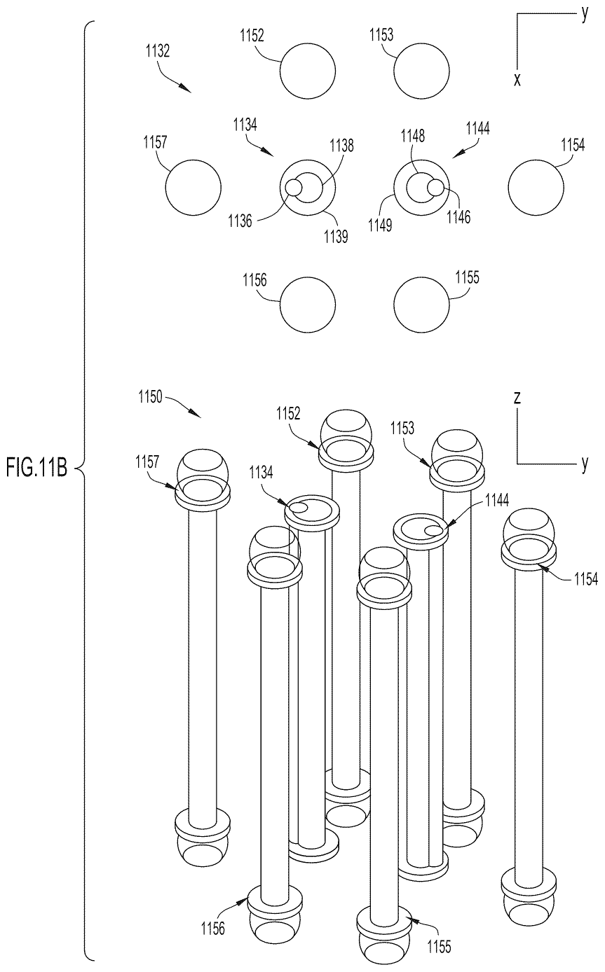

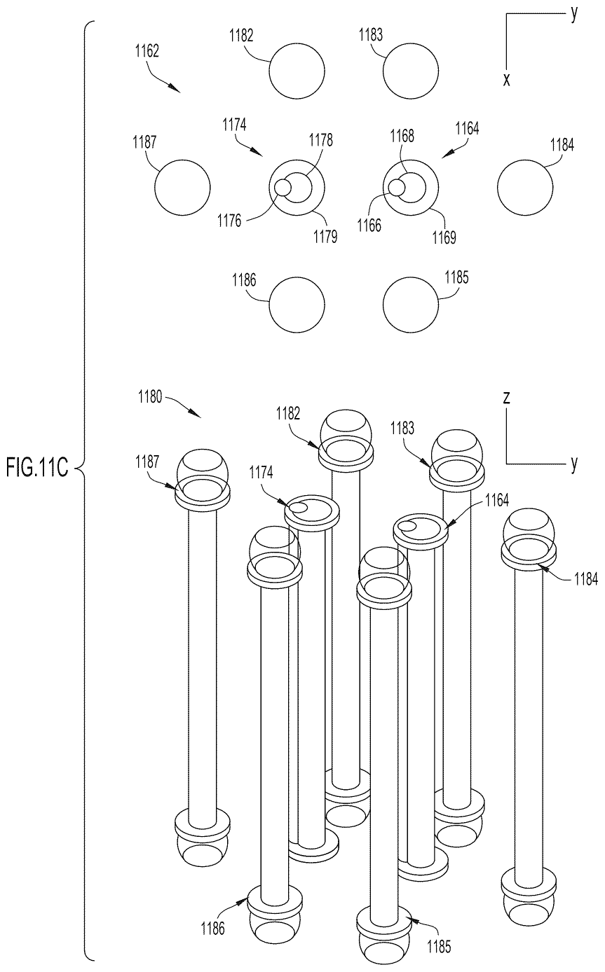

FIG. 10 depicts a third aspect of a manufacturing process of a via which includes creating a first drill hole and a second drill hole from the same side of the PCB and, after the via is created, filling the via with epoxy in accordance with an embodiment. FIG. 10 includes steps 1001 to 1005 of a manufacturing process. Step 1001 indicates creating a first drill hole by drilling a first cylindrical hole 1012 from a first side of a PCB 1015 using a drill bit 1017. It can be noted that the drill bit 1017 may be of a size that correlates to a first predetermined diameter for the first cylindrical hole 1012. The first cylindrical hole 1012 may be drilled up to a first predetermined depth 1019 into the PCB 1015, which may be up to the full depth of the PCB 1015, as shown.

Step 1002 indicates creating a second cylindrical hole 1032 that overlaps with the first cylindrical hole 1012 from the first side of the PCB 1015 using a drill bit 1037, up to a second predetermined depth. It is appreciated that the central axis of the second cylindrical hole 1032 is at an offset from the central axis of the first cylindrical hole 1012. It should be noted that the drill bit 1037 may be of a size that correlates to a second predetermined diameter for the second cylindrical hole 1032. A via 1050 is created when the first cylindrical hole 1012 and the second cylindrical hole 1032 overlap in the PCB 1015.

Step 1003 indicates plating the via 1050 with copper, for example, copper plates 1033 and 1033′. Step 1004 indicates the process of back drilling from a second side of the PCB 1015. Back drilling includes creating the third cylindrical hole 1052, while removing the excess plating of the via 1050 and modifying the via 1050 to create via 1050′ including the back drilled hole 1052. Step 1004 may include addressing a depth of the via that is incorporated by the back drilled third cylindrical hole 1052. Step 1005 indicates filling the via 1050′ with epoxy 1072 and adding copper plate 1075 on top of the via 1050′ that is filled with epoxy 1072.

FIG. 11A-11C depict different configurations of creating adjacent vias on a PCB using a double drilling process in accordance with an embodiment. Adjacent vias on a PCB may impact the target impedance of each via. For this reason, two drill holes of a via created using a double drilling process may be drilled in a particular configuration and similarly, two drill holes of adjacent vias may be drilled in a particular configuration with respect to each other to effectively reduce the impact if adjacent vias on the target impedance of the vias. This may result in different configurations of creating adjacent vias, including but not limited to including, inner-inner double drilling, outer-outer double drilling, and inner-outer double drilling. It is to be appreciated that there may be other configurations of creating adjacent vias using a double drilling process.

Turning to FIG. 11A, FIG. 11A depicts an inner-inner configuration of adjacent vias created using a double drilling process. FIG. 11A includes a top view 1102 of the adjacent vias having the inner-inner configuration and a perspective view 1120 of the adjacent vias having the inner-inner configuration. Via 1104 and via 1114 are illustrated in the top view 1102 of adjacent vias. Via 1104 includes two drill holes, a first drill hole 1106 and a second drill hole 1108. Via 1104 includes a circular feature 1109 representing one of the pads, including, but not limited to, a top pad, a bottom pad, and an anti-pad. Via 1114 includes two drill holes, a first drill hole 1116 and a second drill hole 1118. Via 1114 includes a circular feature 1119 representing one of the pads, including, but not limited to, a top pad, a bottom pad, and an anti-pad.

The first drill hole 1106 of via 1104 and the first drill hole 1116 of via 1114 are facing each other. With respect to the adjacent vias 1104 and 1114, the first drill holes 1106, 1116 appear to be on inner sides of the second drill hole 1108 of via 1104 and second drill hole 1118 of via 1114. Due to this reason, the configuration of adjacent vias depicted in top view 1102 may be referred to as inner-inner configuration. Top view 1102 includes ground vias 1122, 1123, 1124, 1125, 1126, 1127 surrounding the two double drilled vias 1104 and 1114. Generally, ground vias include a single drill hole created using standard drilling process along the height of a PCB to connect different layers of the PCB to a ground plane. Perspective view 1120 depicts a perspective view of the adjacent vias 1104 and 1114 created in the inner-inner configuration and the surrounding ground vias 1122, 1123, 1124, 1125, 1126, 1127.

Turning to FIG. 11B, FIG. 11B depicts an outer-outer configuration of adjacent vias created using a double drilling process. FIG. 11B includes a top view 1132 of the adjacent vias having the outer-outer configuration and a perspective view 1150 of the adjacent vias having the outer-outer configuration. Via 1134 and via 1144 are illustrated in the top view 1132 of adjacent vias. Via 1134 includes two drill holes, a first drill hole 1136 and a second drill hole 1138. Via 1134 includes a circular feature 1139 representing one of the pads, including, but not limited to, a top pad, a bottom pad, and an anti-pad. Via 1144 includes two drill holes, a first drill hole 1146 and a second drill hole 1148. Via 1144 includes a circular feature 1149 representing one of the pads, including, but not limited to, a top pad, a bottom pad, and an anti-pad.

The first drill hole 1136 of via 1134 is on an outer side of the second drill hole 1138 of via 1134. Similarly, the first drill hole 1146 of via 1144 is on an outer side of the second drill hole 1148 of via 1144. With respect to the adjacent vias 1134 and 1144, the first drill holes 1136, 1146 appear to be on opposite direction of outer sides of the second drill hole 1138 of via 1134 and second drill hole 1148 of via 1144. Due to this reason, the configuration of adjacent vias depicted in top view 1132 may be referred to as outer-outer configuration. Top view 1132 includes ground vias 1152, 1153, 1154, 1155, 1156, 1157 surrounding the two double drilled vias 1134 and 1144. Perspective view 1150 depicts a perspective view of the adjacent vias 1134 and 1144 created in the outer-outer configuration and the surrounding ground vias 1152, 1153, 1154, 1155, 1156, 1157.

Turning to FIG. 11C, FIG. 11C depicts an inner-outer configuration of adjacent vias created using a double drilling process. FIG. 11C includes a top view 1162 of the adjacent vias having the inner-outer configuration and a perspective view 1180 of the adjacent vias having the inner-outer configuration. Via 1164 and via 1174 are illustrated in the top view 1162 of adjacent vias. Via 1164 includes two drill holes, a first drill hole 1166 and a second drill hole 1168. Via 1164 includes a circular feature 1169 representing one of the pads, including, but not limited to, a top pad, a bottom pad, and an anti-pad. Via 1174 includes two drill holes, a first drill hole 1176 and a second drill hole 1178. Via 1174 includes a circular feature 1179 representing one of the pads, including, but not limited to, a top pad, a bottom pad, and an anti-pad.

The first drill hole 1166 of via 1164 is on an inner side of the second drill hole 1168 of via 1164. However, the first drill hole 1176 of via 1174 is on an outer side of the second drill hole 1178 of via 1174. With respect to the adjacent vias 1164 and 1174, the first drill holes 1166, 1176 appear to be in the same direction of the respective second drill holes 1168 and 1148. This configuration of adjacent vias depicted in top view 1162 may be referred to as inner-outer configuration. Top view 1162 includes ground vias 1182, 1183, 1184, 1185, 1186, 1187 surrounding the two double drilled vias 1164 and 1174. Perspective view 1180 depicts a perspective view of the adjacent vias 1164 and 1174 created in the inner-outer configuration and the surrounding ground vias 1182, 1183, 1184, 1185, 1186, 1187

Simulations are performed by creating vias on a PCB in a simulation tool to test and compare impedance tuning for specific scenarios including, (1) adjacent vias created using standard drilling process (not having non-functional pads), (2) adjacent vias created using standard drilling process and having non-functional pads, (3) adjacent vias having an inner-inner configuration and created using a double drilling process, (4) adjacent vias having an outer-outer configuration and created using the double drilling process, and (5) adjacent vias having an inner-outer configuration and created using the double drilling process.

In order to assess and compare impedance tuning in vias, the time domain reflectometry (TDR) measuring technique may be used. A TDR measuring technique includes sending a short electrical pulse through vias and observing the reflected signals. For testing scenarios that include creating vias using a double drilling process, a drill bit of size 5.9 mil may be used for the first drill hole and a drill bit of size 9.8 mil may be used for the second drill hole with a distance of approximately 5 mil between the central axis of the first drill hole and the central axis of the second drill hole, resulting in a tuned impedance of approximately 85 ohm. However, it should be noted that the simulation tests may be equally applied to a double drilling process using other sizes of drill bits and other distances between the central axis of the first drill hole and the central axis of the second drill hole.

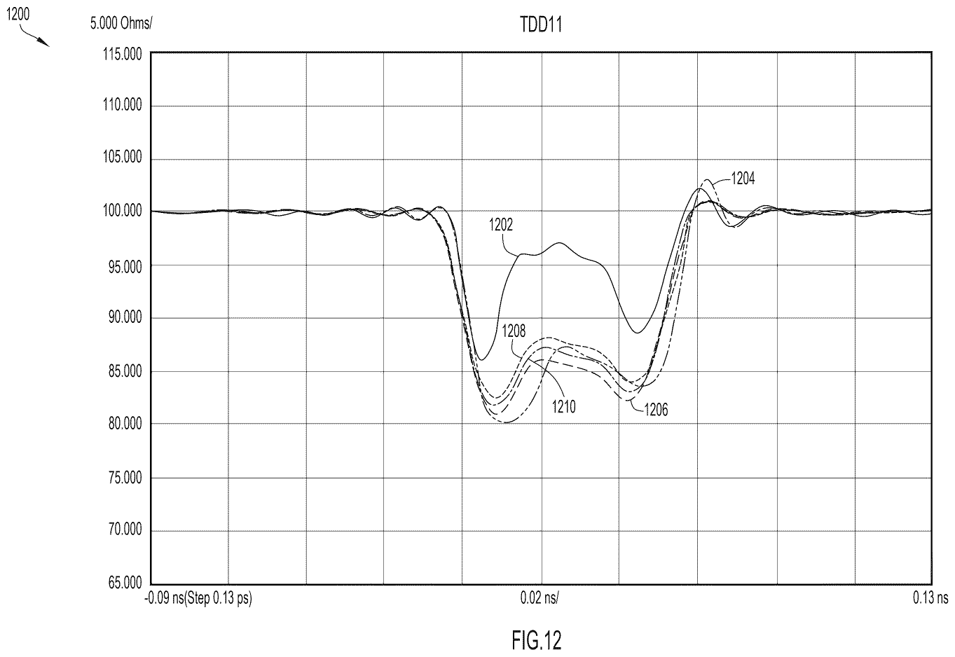

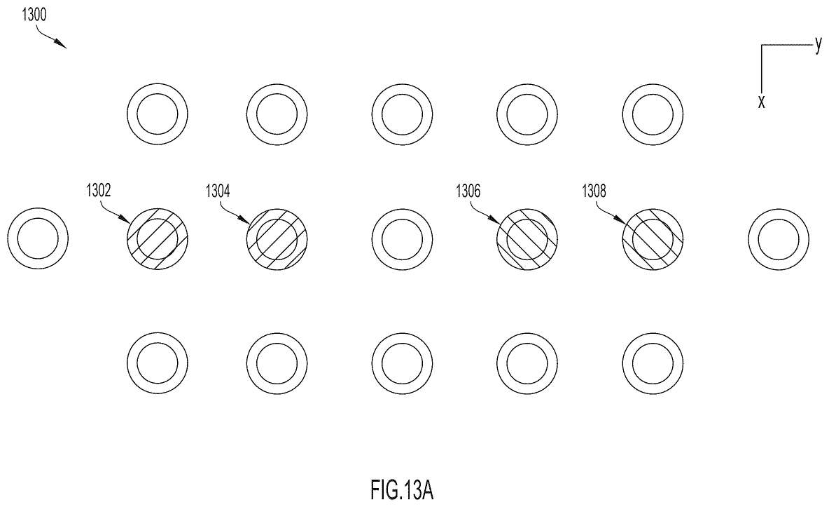

FIG. 12 depicts comparison of TDR simulation results 1200 for the scenarios (1) to (5) in accordance with an embodiment. Curve 1202 depicts TDR results corresponding to simulations performed for vias created using standard drilling process. Curve 1204 depicts TDR results corresponding to simulations performed for vias created using standard drilling process and having non-functional pads. Curve 1206 depicts TDR results corresponding to simulations performed for adjacent vias having an inner-inner configuration and created using a double drilling process. Curve 1208 depicts TDR results corresponding to simulations performed for adjacent vias having an outer-outer configuration and created using the double drilling process. Curve 1210 depicts TDR results corresponding to simulations performed for adjacent vias having an inner-outer configuration and created using the double drilling process. Simulations are performed by creating vias on a PCB in a simulation tool.

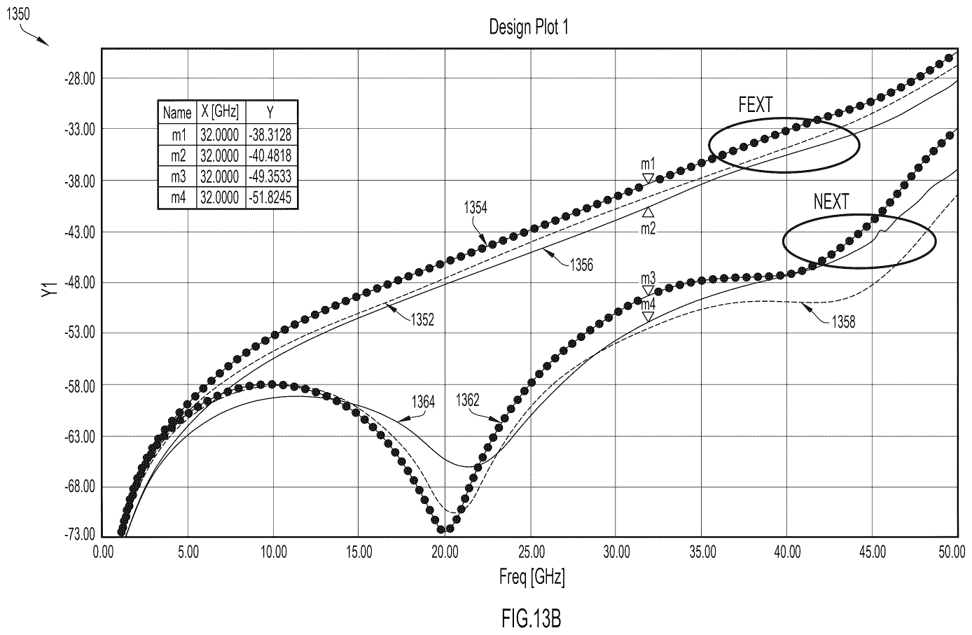

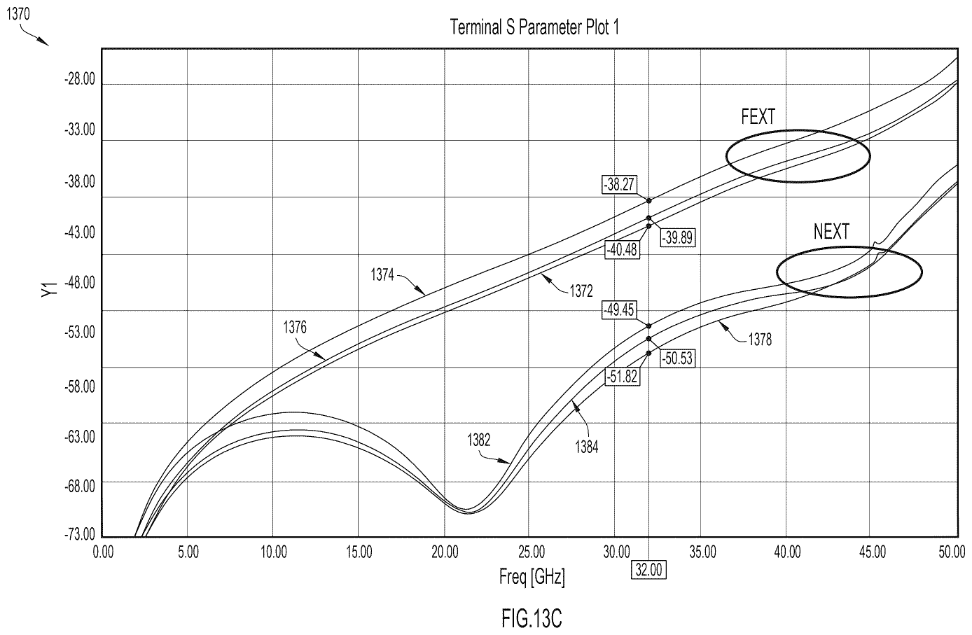

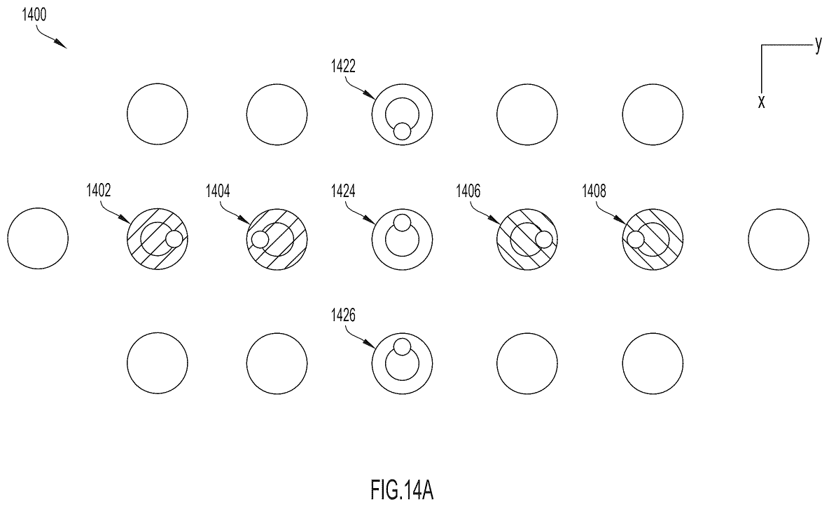

Simulations may also be performed to assess and compare crosstalk generated between adjacent pairs of vias in a BGA pin field for specific scenarios including, (1) vias created using standard drilling process, (2) vias created using standard drilling process and having non-functional pads, and (3) adjacent vias having an inner-inner configuration and created using a double drilling process. Generally, crosstalk is generated between two elements of a PCB, i.e., unwanted energy from a first element (typically called an aggressor) is transferred to another element (typically called victim) that gets affected. FIG. 13A depicts a top view 1300 of adjacent pairs of vias created on a PCB for simulation purposes. Adjacent pairs of vias include pair-1 with adjacent vias 1302 and 1304 and pair-2 with adjacent vias 1306 and 1308. Other circular features included in the top view 1300 are ground vias created using standard drilling process. Vias 1302, 1304, 1306, 1308 may be created as per one of the three scenarios (1), (2) and (3) as described above. Crosstalk generated between adjacent pairs of vias in a BGA pin field may be primarily measured as far-end crosstalk (FEXT) or near-end crosstalk (NEXT).

FIG. 13B depicts simulation results 1350 and illustrates comparison of FEXT and NEXT for the three scenarios. Curve 1352 depicts FEXT results corresponding to simulations performed for vias created using standard drilling process. Curve 1354 depicts FEXT results corresponding to simulations performed for vias created using standard drilling process and having non-functional pads. Curve 1356 depicts FEXT results corresponding to simulations performed for adjacent vias having an inner-inner configuration and created using a double drilling process. Curve 1358 depicts NEXT results corresponding to simulations performed for vias created using standard drilling process. Curve 1362 depicts NEXT results corresponding to simulations performed for vias created using standard drilling process and having non-functional pads. Curve 1364 depicts NEXT results corresponding to simulations performed for adjacent vias having an inner-inner configuration and created using a double drilling process.

Simulation results in FIG. 13B indicate that the curve 1352 has a median of approximately −39 db. Simulation results in FIG. 13B indicate that FEXT crosstalk is increased for vias created using standard drilling process and having non-functional pads, as compared to vias created using standard drilling process by about 1.17 db. However, simulation results show that for vias having an inner-inner configuration and created using a double drilling process, FEXT crosstalk is decreased from vias created using standard drilling process by about 1 db. Thus, there is an improvement of approximately 2.17 db for vias having an inner-inner configuration and created using a double drilling process over vias created using standard drilling process and having non-functional pads. Simulation results observed for NEXT crosstalk show that NEXT for vias having an inner-inner configuration and created using a double drilling process is improved by about 2.5 db over vias created using standard drilling process and having non-functional pads.

Simulations may also be performed to assess and compare crosstalk, primarily FEXT and NEXT, generated between adjacent pairs of vias in a BGA pin field for specific scenarios including, (1) adjacent vias having an inner-inner configuration and created using a double drilling process, (2) adjacent vias having an outer-outer configuration and created using the double drilling process, and (3) adjacent vias having an inner-outer configuration and created using the double drilling process.

FIG. 13C depicts simulation results 1370 and illustrates comparison of FEXT and NEXT for the three scenarios. Curve 1372 depicts FEXT results corresponding to simulations performed for adjacent vias having an inner-inner configuration and created using a double drilling process. Curve 1374 depicts FEXT results corresponding to simulations performed for adjacent vias having an outer-outer configuration and created using the double drilling process. Curve 1376 depicts FEXT results corresponding to simulations performed for adjacent vias having an inner-outer configuration and created using the double drilling process. Curve 1378 depicts NEXT results corresponding to simulations performed for adjacent vias having an inner-inner configuration and created using a double drilling process. Curve 1382 depicts NEXT results corresponding to simulations performed for adjacent vias having an outer-outer configuration and created using the double drilling process. Curve 1384 depicts NEXT results corresponding to simulations performed for adjacent vias having an inner-outer configuration and created using the double drilling process.

Simulations may be modified to incorporate ground vias that are created using a double drilling process. As such, simulations are now performed to assess and compare crosstalk primarily FEXT and NEXT, generated between adjacent pairs of vias in a BGA pin field for specific scenarios including, (1) adjacent pairs of vias created using standard drilling process, (2) adjacent pairs of vias created using standard drilling process and having non-functional pads, (3) adjacent pair of vias having an inner-inner configuration and created using a double drilling process, and (4) adjacent pair of vias having an inner-inner configuration and ground vias, all created using a double drilling process.

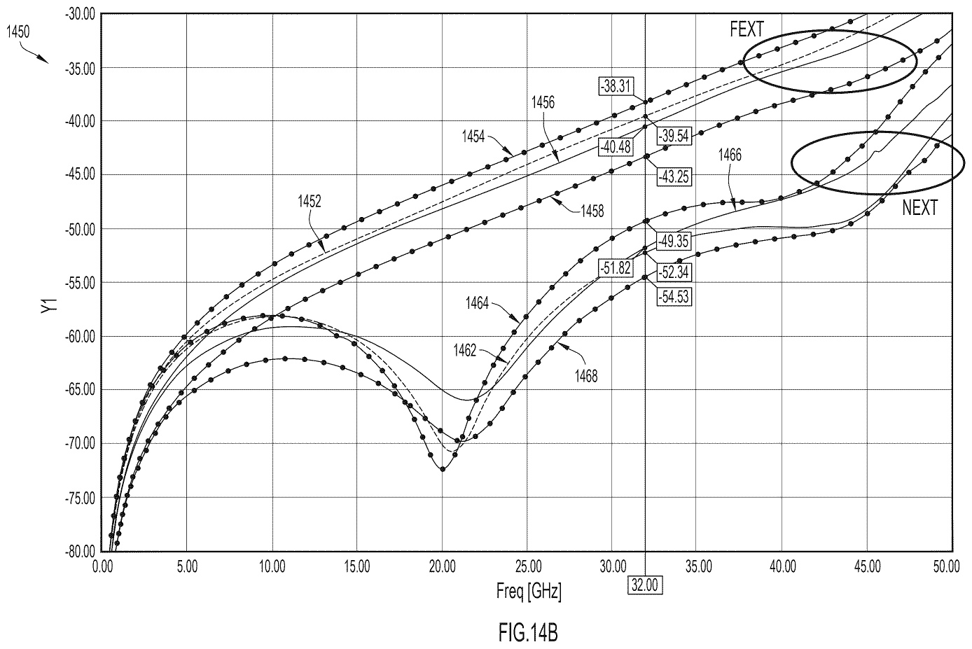

FIG. 14A depicts a top view 1400 of adjacent pairs of vias and ground vias created on a PCB using a double drilling process for simulation purposes. Adjacent pairs of vias include pair-1 with adjacent vias 1402 and 1404 and pair-2 with adjacent vias 1406 and 1408. Top view 1400 includes ground vias created using the double drilling process, such as, for example ground vias 1422, 1424 and 1426, and other ground vias (not marked) created using the standard drilling process.

FIG. 14B depicts simulation results 1450 and illustrates a comparison of FEXT for the four scenarios described above. Curve 1452 depicts FEXT results corresponding to simulations performed for adjacent vias created using a standard drilling process. Curve 1454 depicts FEXT results corresponding to simulations performed for adjacent vias created using standard drilling process and having non-functional pads. Curve 1456 depicts FEXT results corresponding to simulations performed for adjacent vias having an inner-inner configuration and created using a double drilling process. Curve 1458 depicts FEXT results corresponding to simulations performed for adjacent vias having an inner-inner configuration and ground vias, all created using the double drilling process.

In addition, simulation results 1450 illustrates a comparison of NEXT for the four scenarios described above. Curve 1462 depicts NEXT results corresponding to simulations performed for adjacent vias created using a standard drilling process. Curve 1464 depicts NEXT results corresponding to simulations performed for adjacent vias created using standard drilling process and having non-functional pads. Curve 1466 depicts NEXT results corresponding to simulations performed for adjacent vias having an inner-inner configuration and created using the double drilling process. Curve 1468 depicts NEXT results corresponding to simulations performed for adjacent vias having an inner-inner configuration and ground vias, all created using the double drilling process.

Simulation results in FIG. 14B indicate that the crosstalk generated between adjacent pairs of vias is improved by using ground vias created using the double drilling process between the adjacent pairs of vias. FIG. 14B shows that the improvement for FEXT generated between adjacent vias created using a double drilling process is about 4.95 db as compared to adjacent vias created using standard drilling process and having non-functional pads. The improvement for FEXT generated between adjacent vias created using a double drilling process is about 3.71 db in comparison to adjacent vias created using a standard drilling process (not having non-functional pads).

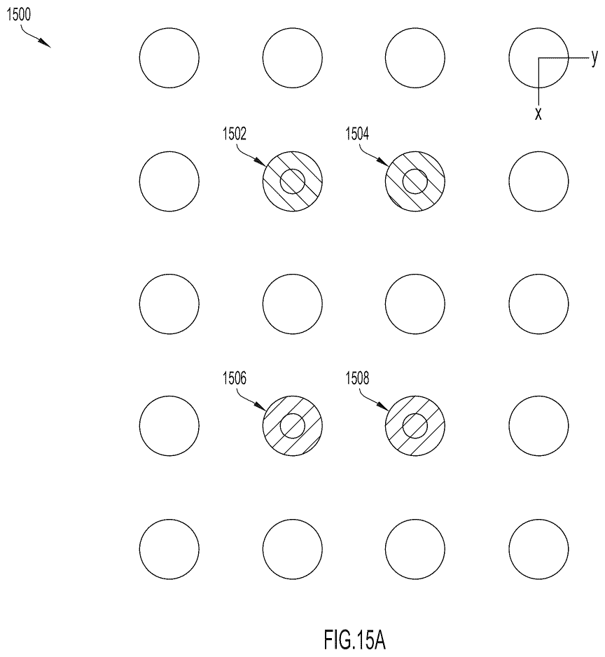

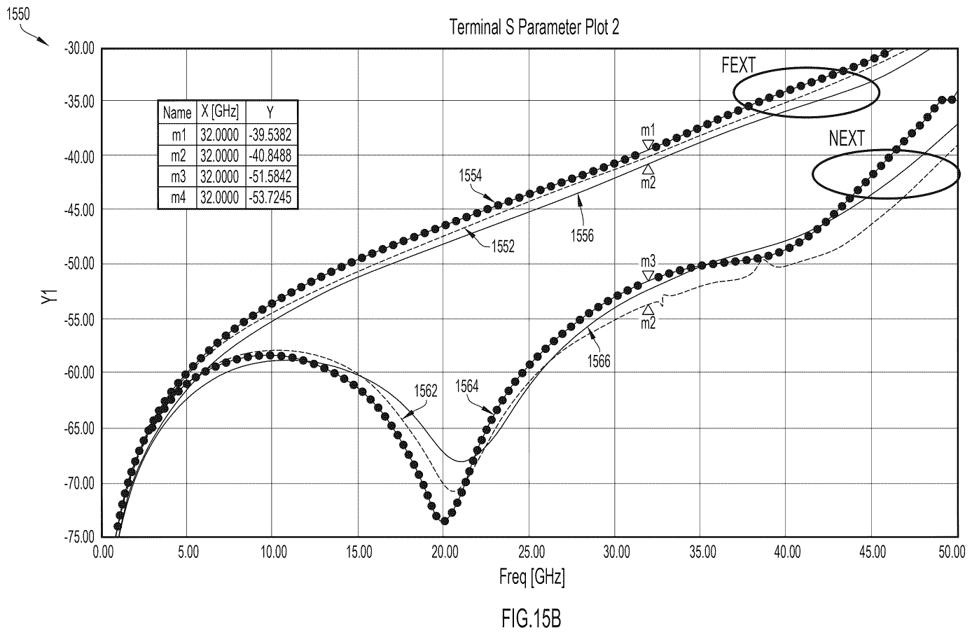

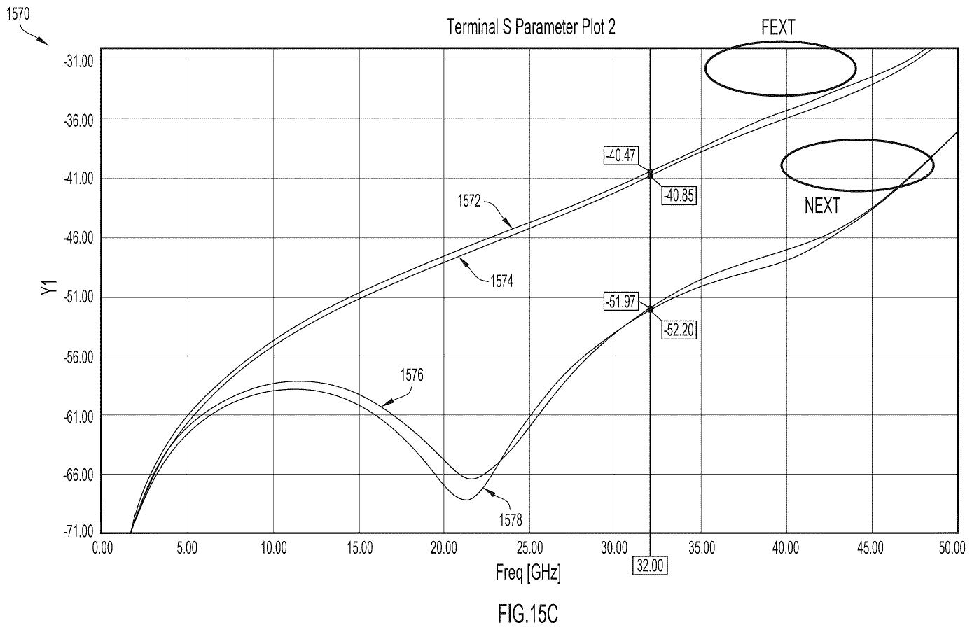

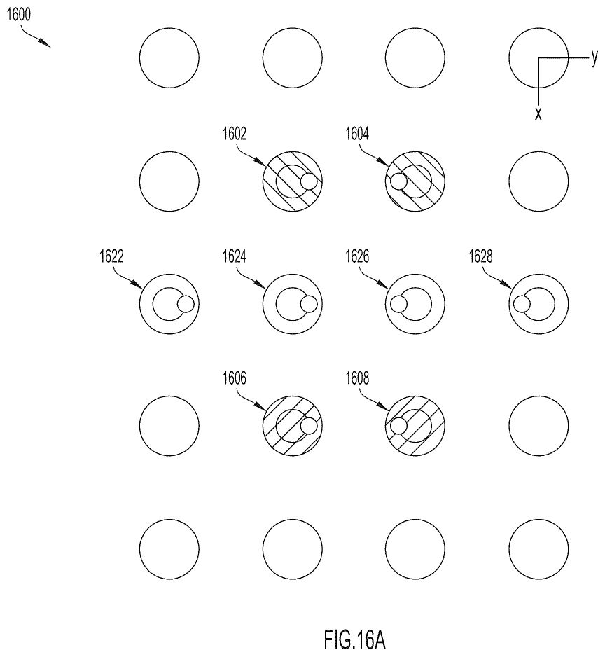

Simulations may be performed to assess and compare crosstalk, primarily FEXT and NEXT, generated between pairs of vias facing each other in a BGA pin field as shown in FIG. 15A. The simulation are performed for specific scenarios including, (1) pairs of vias created using standard drilling process, (2) pairs of vias created using standard drilling process and having non-functional pads, and (3) pairs of vias having an inner-inner configuration and created using a double drilling process.

FIG. 15A depicts a top view 1500 of pairs of vias facing each other in a BGA pin field created on a PCB using the double drilling process for simulation purposes. Pairs of vias facing each other in a BGA pin field include pair-1 with adjacent vias 1502 and 1504 and pair-2 with adjacent vias 1506 and 1508. Top view 1500 includes ground vias (not marked) created using the standard drilling process.

FIG. 15B depicts simulation results 1550 and illustrates comparison of FEXT and NEXT for the four scenarios discussed above. Curve 1552 depicts FEXT results corresponding to simulations performed for vias created using a standard drilling process. Curve 1554 depicts FEXT results corresponding to simulations performed for vias created using standard drilling process and having non-functional pads. Curve 1556 depicts FEXT results corresponding to simulations performed for vias having an inner-inner configuration and created using the double drilling process. Curve 1562 depicts NEXT results corresponding to simulations performed for vias created using a standard drilling process. Curve 1564 depicts NEXT results corresponding to simulations performed for vias created using standard drilling process and having non-functional pads. Curve 1566 depicts NEXT results corresponding to simulations performed for vias having an inner-inner configuration and created using the double drilling process.

Simulation results in FIG. 15B show that the crosstalk generated between pairs of vias facing each other in a BGA pin field and created using the double drilling process is improved as compared to adjacent vias created using standard drilling process and having non-functional pads FIG. 15B shows that the improvement for FEXT generated is about 1.31 db at approximately 32 GHz.

Simulations may be performed for comparing the different configurations of drill holes created using the double drilling process, such as (1) inner-inner configuration and (2) outer-outer configuration. FIG. 15C shows the simulation results 1570 for these scenarios. Curve 1572 depicts FEXT results corresponding to simulations performed for vias having an inner-inner configuration. Curve 1574 depicts FEXT results corresponding to simulations performed for vias having an outer-outer configuration. Curve 1576 depicts NEXT results corresponding to simulations performed for vias having an inner-inner configuration. Curve 1578 depicts NEXT results corresponding to simulations performed for vias having an outer-outer configuration. Simulation results in FIG. 15C show that the inner-inner configuration of vias have an improved performance over outer-outer configuration of vias. The inner-inner configuration of vias are generally more coupled toward each other, and improved performance may result.

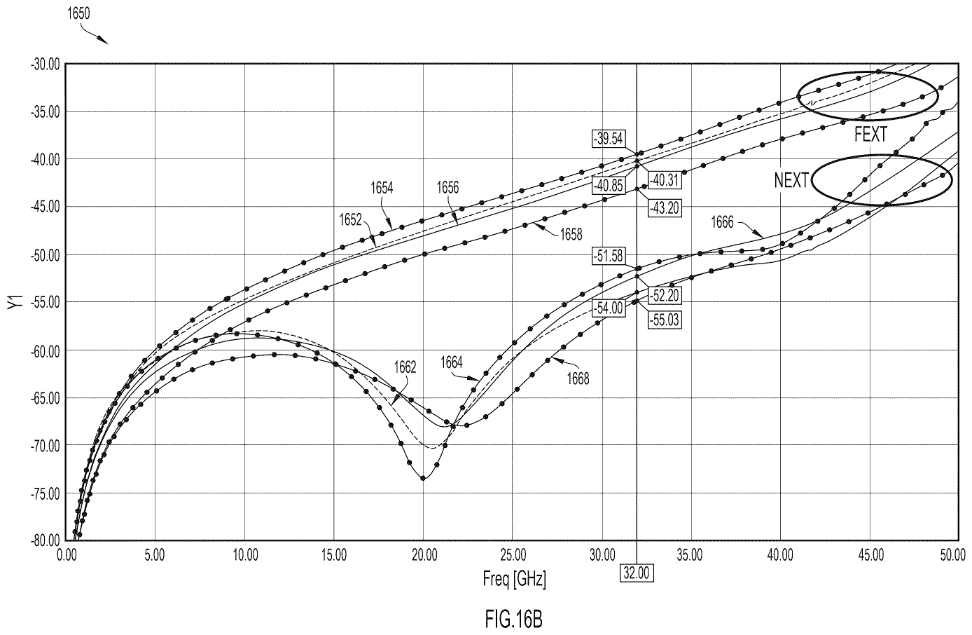

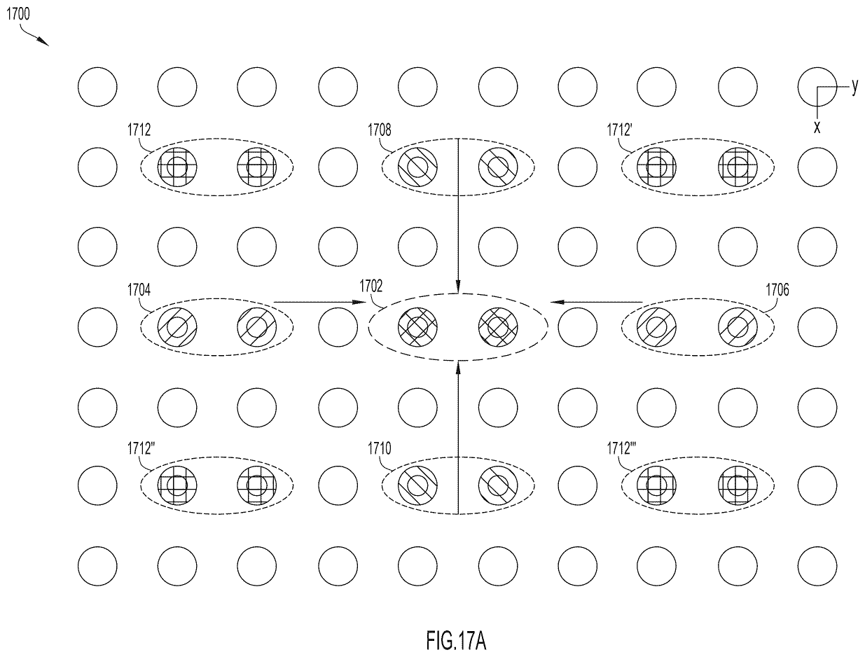

Simulations performed to assess and compare crosstalk generated between pairs of vias facing each other in a BGA pin field are modified to include ground vias created using the double drilling process as shown in FIG. 16A. Simulations are performed for specific scenarios including, (1) pairs of vias created using standard drilling process, (2) pairs of vias created using standard drilling process and having non-functional pads, (3) pairs of vias having an inner-inner configuration and created using a double drilling process, and (4) pairs of vias having an inner-inner configuration and ground vias, all created using a double drilling process.

FIG. 16A depicts a top view 1600 of pairs of vias facing each other in a BGA pin field and surrounding ground vias created on a PCB using the double drilling process for simulation purposes. Pairs of vias facing each other in a BGA pin field include pair-1 with adjacent vias 1602 and 1604 and pair-2 with adjacent vias 1606 and 1608. Top view 1600 includes ground vias created using the double drilling process and placed between the two pairs, pair-1 and pair-2, such as, for example ground vias 1622, 1624, 1626, and 1628, and other ground vias (not marked) created using the standard drilling process.

FIG. 16B depicts simulation results 1650 and illustrates comparison of FEXT for the four scenarios. Curve 1652 depicts FEXT results corresponding to simulations performed for vias created using a standard drilling process. Curve 1654 depicts FEXT results corresponding to simulations performed for vias created using standard drilling process and having non-functional pads. Curve 1656 depicts FEXT results corresponding to simulations performed for vias having an inner-inner configuration and created using the double drilling process. Curve 1658 depicts FEXT results corresponding to simulations performed for vias having an inner-inner configuration and ground vias, all created using the double drilling process.

In addition, simulation results 1650 illustrate a comparison of NEXT for the four scenarios discussed above. Curve 1662 depicts NEXT results corresponding to simulations performed for vias created using a standard drilling process. Curve 1664 depicts NEXT results corresponding to simulations performed for vias created using standard drilling process and having non-functional pads. Curve 1666 depicts NEXT results corresponding to simulations performed for vias having an inner-inner configuration and created using the double drilling process. Curve 1668 depicts NEXT results corresponding to simulations performed for vias having an inner-inner configuration and ground vias, all created using the double drilling process.

Simulation results in FIG. 16B show that the crosstalk generated between pairs of vias facing each other in a BGA pin field is improved by including ground vias created using the double drilling process and positioned in between the pairs of vias facing each other. FIG. 16B shows that the improvement for FEXT generated is about 3.66 db at 32 GHz as compared to vias created using standard drilling process and having non-functional pads and about 3.45 db at approximately 32 GHz as compared to vias created using standard drilling process.

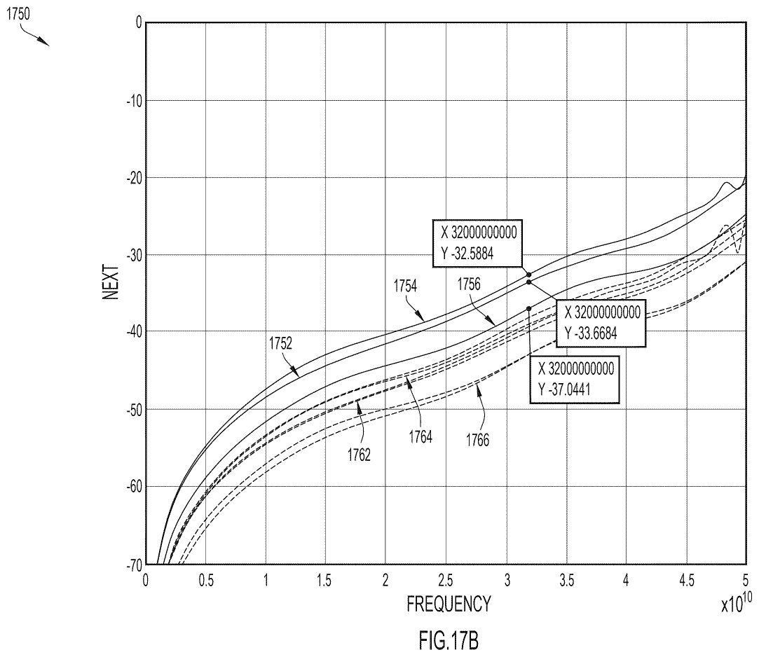

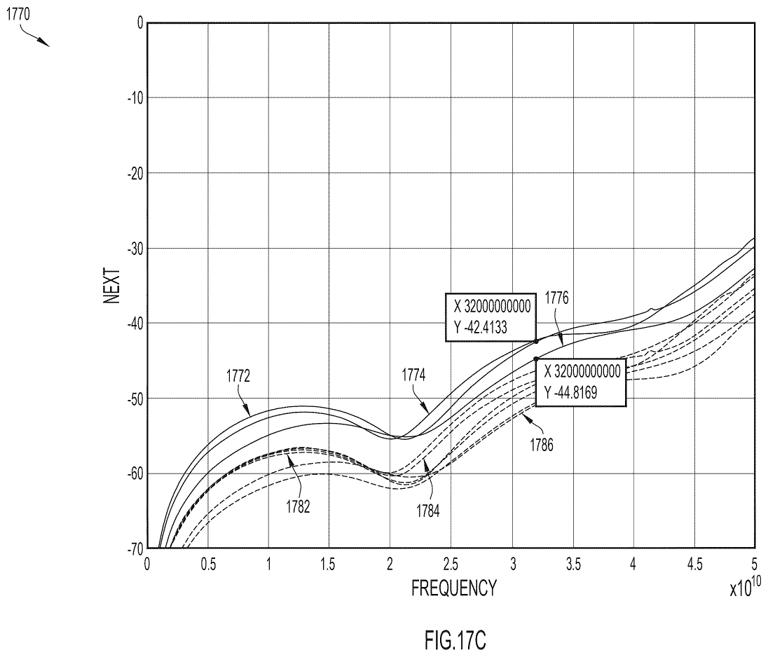

Simulations may be performed to evaluate power sum crosstalk generated in a BGA pin field. FIG. 17A depicts a top view 1700 of a BGA pin field on a PCB including multiple vias. Power sum crosstalk may be generated on a central pair of adjacent vias, such as the central pair of vias 1702 (victim) in the center of the BGA pin filed that is impacted by other pairs of vias (i.e., aggressor vias). For example, adjacent aggressors, such as, pair-1 of adjacent vias 1704 and pair-2 of adjacent vias 1706, that are adjacent to the central pair of vias 1702; and facing aggressors, such as, pair-3 of adjacent vias 1708 and pair-4 of adjacent vias 1710, that face the central pair of vias 1702. The impact of other pairs of vias such as pairs 1712, 1712′, 1712″, or 1712′″ on the central pair of adjacent vias 1702 is generally not significant.

Simulations for power sum crosstalk generated in BGA pin field are evaluated for scenarios including, (1) vias created using a standard drilling process, (2) vias created using a standard drilling process and having non-functional pads, (3) vias surrounded by ground vias, all created using a double drilling process. FIG. 17B and FIG. 17C depict simulation results for power sum crosstalk generated in BGA pin field.

FIG. 17B depicts simulation results 1750 for FEXT generated in BGA pin field. Curve 1752 depicts FEXT results for vias created using a standard drilling process. Curve 1754 depicts FEXT results for vias created using standard drilling process and having non-functional pads. Curve 1756 depicts FEXT results for vias having an inner-inner configuration and ground vias, all created using the double drilling process. Curve 1762 depicts FEXT generated from individual aggressor vias created using a standard drilling process. Curve 1764 depicts FEXT generated due to individual aggressor vias created using standard drilling process and having non-functional pads. Curve 1766 depicts FEXT generated due to individual aggressor vias having an inner-inner configuration and ground vias, all created using the double drilling process. Simulation results 1750 show that FEXT power sum crosstalk generated from vias created using the double drilling process is improved by approximately 3.38 db over vias created using the standard drilling process at approximately 32 GHz and by approximately 4.54 db over vias created using the standard drilling process and having non-functional pads at approximately 32 GHz.

FIG. 17C depicts simulation results 1770 for NEXT generated in BGA pin field. Curve 1772 depicts NEXT results for vias created using a standard drilling process. Curve 1774 depicts NEXT results for vias created using standard drilling process and having non-functional pads. Curve 1776 depicts NEXT results for vias having an inner-inner configuration and ground vias, all created using the double drilling process. Curve 1782 depicts NEXT results for individual aggressors created using a standard drilling process. Curve 1784 depicts NEXT results for individual aggressors created using standard drilling process and having non-functional pads. Curve 1786 depicts NEXT results for individual aggressors having an inner-inner configuration and ground vias, all created using the double drilling process. Simulation results 1770 show that NEXT power sum crosstalk generated for vias created using the double drilling process is improved by 2.4 db over vias created using the standard drilling process and over vias having non-functional pads.

Simulation results depict that a double-drilled via, i.e., a via created using the double drilling process has higher bandwidth than a via created using standard drilling process and having non-functional pad. For example, results depict that a double-drilled via has 10 GHz more bandwidth than via created using standard drilling process and having non-functional pad. It is to be understood that vias created using standard drilling process and having non-functional pads are more resistive due to the surface area of the non-functional pads.

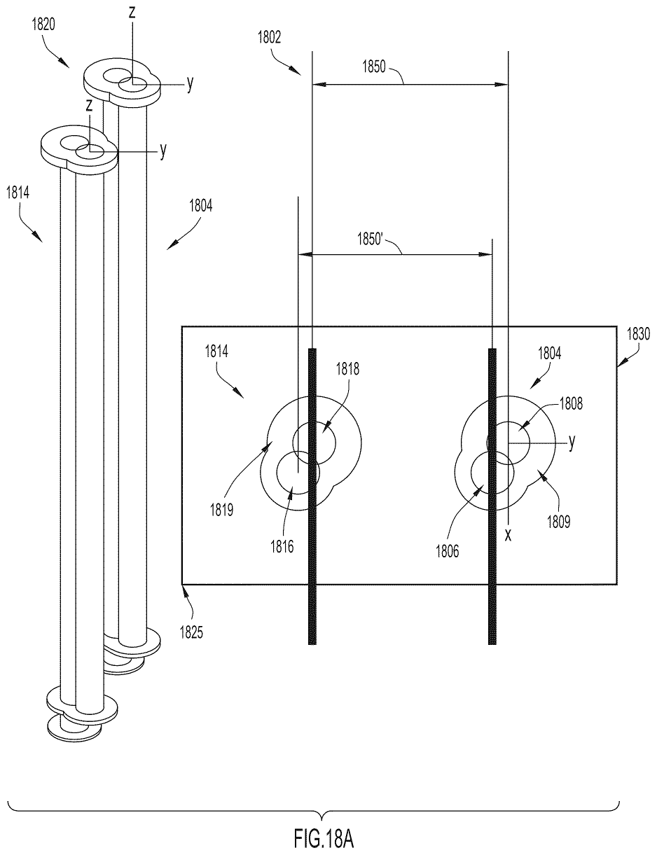

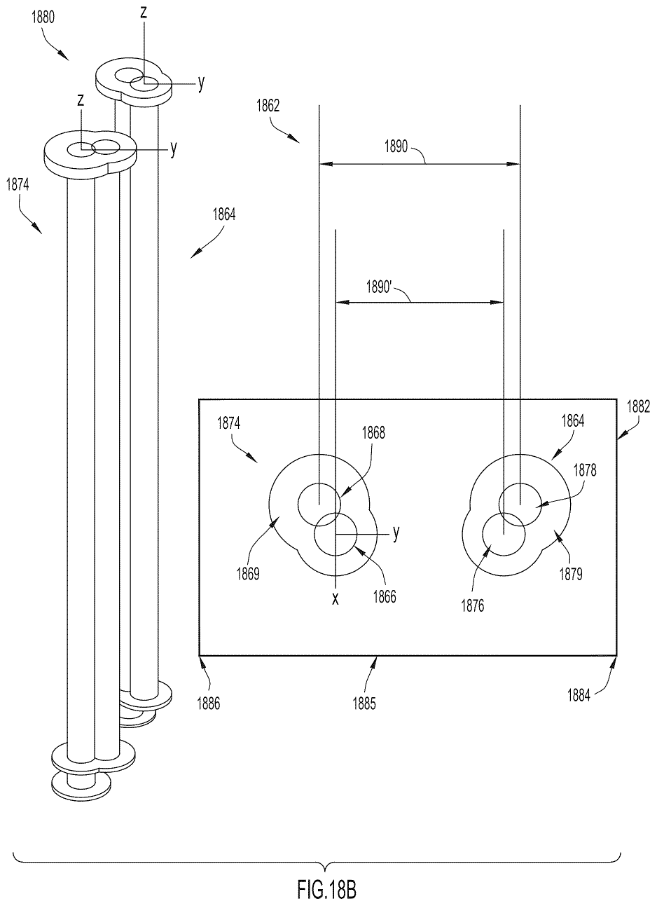

Turning to FIG. 18A, FIG. 18A depicts a first arrangement of adjacent vias created in a PCB using a double drilling process in which first drill holes of each of the adjacent vias are drilled on a same side of the respective second drill holes and at a particular position. The particular position of the first drill holes may relate to facing a particular corner of the PCB. This arrangement of adjacent vias may be referred to as cornered adjacent vias. FIG. 18A includes a top view 1802 and a perspective view 1820 of the cornered adjacent vias. Via 1804 and via 1814 are illustrated in the top view 1802 of adjacent vias, drilled in a PCB 1830. Via 1804 includes two drill holes, a first drill hole 1806 and a second drill hole 1808, in which the first drill hole 1806 is drilled to face a corner 1825 of the PCB 1830. It is to be appreciated that the first drill hole 1806 may be drilled to face any other corners of the PCB 1830. Via 1804 includes a circular feature 1809 representing one of the pads, including, but not limited to, a top pad, a bottom pad, and an anti-pad.

Via 1814 includes two drill holes, a first drill hole 1816 and a second drill hole 1818, in which the first drill hole 1816 is drilled to face the corner 1825 of the PCB 1830 (same as the first drill hole 1806 of the via 1804). First drill hole 1806 of via 1804 and first drill hole 1816 of via 1814 are drilled on a same side of the respective second drill holes 1808 and 1818. Via 1814 includes a circular feature 1819 representing one of the pads, including, but not limited to, a top pad, a bottom pad, and an anti-pad. It is to be noted that for cornered adjacent vias, a distance 1850 between the centers of first drill holes 1806 and 1816 may be approximately the same as a distance 1850′ between the centers of second drill holes 1808 and 1818. Perspective view 1820 depicts a perspective view of the cornered adjacent vias 1804 and 1814.

FIG. 18B depicts a second arrangement of adjacent vias created in a PCB using a double drilling process in which first drill holes of each of the adjacent vias are drilled facing each other (i.e., on opposite sides of the respective second drill holes) and at a particular position. In the second arrangement of adjacent vias, one first drill hole may be drilled to face a first corner associated to a side of the PCB and the other first drill hole may be drilled to face of a second (opposite) corner associated to the same side of the PCB. This arrangement of adjacent vias may be referred to as centered adjacent vias with the first drill holes effectively located in approximately the center (i.e., in between) of the adjacent vias. FIG. 18B includes a top view 1862 and a perspective view 1880 of the centered adjacent vias.

Via 1864 and via 1874 are illustrated in the top view 1862 of centered adjacent vias drilled into a PCB 1882. Via 1864 includes two drill holes, a first drill hole 1866 and a second drill hole 1868, in which the first drill hole 1866 is drilled facing the via 1874 and effectively a corner 1884 associated to a side 1885 of the PCB 1882. Via 1864 includes a circular feature 1869 representing one of the pads, including, but not limited to, a top pad, and a bottom pad. Via 1874 includes two drill holes, a first drill hole 1876 and a second drill hole 1878, in which the first drill hole 1876 is drilled facing the via 1864 and effectively a corner 1886 (opposite to the corner 1884) associated to the side 1885 of the PCB 1882. Via 1874 includes a circular feature 1879 representing one of the pads, including, but not limited to, a top pad, and a bottom pad. Centered adjacent vias 1864 and 1874 have the first drill holes 1866 and 1876 are effectively located in approximately the center of (i.e., in between) the adjacent vias 1864 and 1874. It is to be noted that a distance 1890 between the centers of first drill holes 1866 and 1876 may be less than a distance 1890′ between the centers of second drill holes 1868 and 1878. Perspective view 1880 depicts a perspective view of the centered adjacent vias 1864 and 1874.

In some aspects, the techniques described herein relate to a method, including: drilling a first cylindrical drill hole, on a printed circuit board (PCB), the first cylindrical drill hole having a first diameter and a first central axis, wherein drilling the first cylindrical drill hole includes drilling the first cylindrical drill hole to a first predetermined depth using a first drill bit; and drilling a second cylindrical drill hole on the PCB, the second cylindrical drill hole having a second diameter and a second central axis, wherein drilling the second cylindrical drill hole includes drilling the second cylindrical drill hole to a second predetermined depth using a second drill bit, wherein the second cylindrical drill hole overlaps with the first cylindrical drill hole with the second central axis offset from the first central axis to create a via.

In some aspects, the techniques described herein relate to a method, wherein drilling the first cylindrical drill hole includes drilling a first drill hole to create a drill slot; and drilling the drill slot to the first predetermined depth to create the first cylindrical drill hole.

In some aspects, the techniques described herein relate to a method, further including plating one or more copper plates along an inner surface of the via to create a plated via.

In some aspects, the techniques described herein relate to a method, further including filling the plated via with epoxy.

In some aspects, the techniques described herein relate to a method, further including: back drilling a third cylindrical drill hole from a bottom side of the printed circuit board and filling the third cylindrical drill hole with epoxy, wherein the third cylindrical drill hole has a third central axis that is same as the second central axis of the second cylindrical drill hole and wherein the third cylindrical drill hole is incorporated in the via.

In some aspects, the techniques described herein relate to a method, wherein the first diameter of the first cylindrical drill hole is smaller than or equal to the second diameter of the second cylindrical drill hole.

In some aspects, the techniques described herein relate to a method, wherein drilling the first cylindrical drill hole includes drilling the first cylindrical drill hole from a first side of the printed circuit board and drilling the second cylindrical drill hole includes drilling the second cylindrical drill hole from a second side of the printed circuit board.

In some aspects, the techniques described herein relate to a method, wherein a diameter of at least one of the first drill bit and the second drill bit is 5.9 mil.

In some aspects, the techniques described herein relate to a method, wherein a diameter of the second drill bit is 9.8 mil.

In some aspects, the techniques described herein relate to a method, further including: drilling adjacent vias on the printed circuit board by selecting at least one configuration from a group including: the first cylindrical drill hole of the via facing a first cylindrical drill hole of an adjacent via; the first cylindrical drill hole of the via and the first cylindrical drill hole of the adjacent via on opposite sides of respective second cylindrical drill holes of the via and the adjacent via; and the first cylindrical drill hole of the via and the first cylindrical drill hole of the adjacent via on same sides of the respective second cylindrical drill holes of the via and the adjacent via.

In some aspects, the techniques described herein relate to an apparatus includes: a substrate with one or more layers; and a double-drilled via created on the substrate through the one or more layers, wherein the double-drilled via, includes: a first cylindrical drill hole that includes a first diameter and a first central axis, wherein the first cylindrical drill hole is drilled up to a first predetermined depth in the substrate using a first drill bit; and a second cylindrical drill hole that includes a second diameter and a second central axis, wherein the second cylindrical drill hole is drilled up to a second predetermined depth in the substrate using a second drill bit, and wherein the second cylindrical drill hole overlaps with the first cylindrical drill hole such that the second central axis is offset from the first central axis.

In some aspects, the techniques described herein relate to an apparatus, wherein the first cylindrical drill hole includes a drill slot.

In some aspects, the techniques described herein relate to an apparatus, wherein the double-drilled via includes one or more copper plates along an inner surface of the double-drilled via.

In some aspects, the techniques described herein relate to an apparatus, wherein the double-drilled via is filled with epoxy.

In some aspects, the techniques described herein relate to an apparatus, wherein the double-drilled via includes a third cylindrical drill hole drilled from a bottom side of the substrate, wherein the third cylindrical drill hole includes a third central axis that is same as the second central axis of the second cylindrical drill hole.

In some aspects, the techniques described herein relate to an apparatus, wherein the first diameter of the first cylindrical drill hole is smaller than or equal to the second diameter of the second cylindrical drill hole.

In some aspects, the techniques described herein relate to an apparatus, includes a second double-drilled via created adjacent to the double-drilled via on the substrate, wherein the double-drilled via and the second double-drilled via have at least one configuration selected from a group including: a first cylindrical drill hole of the second double-drilled via facing the first cylindrical drill hole of the double-drilled via; the first cylindrical drill hole of the second double-drilled via and the first cylindrical drill hole of the double-drilled via on opposite sides of respective second cylindrical drill holes of the second double-drilled via and the double-drilled via; and the first cylindrical drill hole of the second double-drilled via and the first cylindrical drill hole of the double-drilled via on same sides of the respective second cylindrical drill holes of the second double-drilled via and the double-drilled via.

In some aspects, the techniques described herein relate to an apparatus includes: a printed circuit board (PCB) including one or more layers, the PCB having at least one ball grid array (BGA); and a double-drilled via that is formed on the PCB through at least two of the one or more layers, wherein the double-drilled via includes: a first cylindrical drill hole having a first diameter and a first central axis, wherein the first cylindrical drill hole is drilled into the PCB up to a first predetermined depth; and a second cylindrical drill hole having a second diameter and a second central axis, wherein the second cylindrical drill hole is drilled into the PCB up to a second predetermined depth, and wherein the second cylindrical drill hole intersects with the first cylindrical drill hole such that the second central axis is offset from the first central axis.

In some aspects, the techniques described herein relate to an apparatus, wherein one or more copper plates are placed along an inner surface of the double-drilled via and the double-drilled via is filled with epoxy.

In some aspects, the techniques described herein relate to an apparatus, wherein the double-drilled via includes a third cylindrical drill hole drilled from a bottom side of the PCB, wherein the third cylindrical drill hole includes a third central axis that coincides with the second central axis of the second cylindrical drill hole.

### Variations and Implementations

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. A method comprising:
drilling a first cylindrical drill hole, on a printed circuit board (PCB), the first cylindrical drill hole having a first diameter and a first central axis, wherein drilling the first cylindrical drill hole includes drilling the first cylindrical drill hole to a first predetermined depth using a first drill bit; and
drilling a second cylindrical drill hole on the PCB, the second cylindrical drill hole having a second diameter and a second central axis, wherein drilling the second cylindrical drill hole includes drilling the second cylindrical drill hole to a second predetermined depth using a second drill bit, wherein the second cylindrical drill hole overlaps with the first cylindrical drill hole with the second central axis offset from the first central axis to create a via.

2. The method of claim 1, wherein drilling the first cylindrical drill hole includes drilling a first drill hole to create a drill slot drilling the drill slot to the first predetermined depth to create the first cylindrical drill hole.

3. The method of claim 1, further comprising plating one or more copper plates along an inner surface of the via to create a plated via.

4. The method of claim 3, further comprising filling the plated via with epoxy.

5. The method of claim 1, further comprising:
back drilling a third cylindrical drill hole from a bottom side of the printed circuit board and filling the third cylindrical drill hole with epoxy, wherein the third cylindrical drill hole has a third central axis that is same as the second central axis of the second cylindrical drill hole and wherein the third cylindrical drill hole is incorporated in the via.

6. The method of claim 1, wherein the first diameter of the first cylindrical drill hole is smaller than or equal to the second diameter of the second cylindrical drill hole.

7. The method of claim 1, wherein drilling the first cylindrical drill hole includes drilling the first cylindrical drill hole from a first side of the printed circuit board and drilling the second cylindrical drill hole includes drilling the second cylindrical drill hole from a second side of the printed circuit board.

8. The method of claim 1, wherein a diameter of at least one of the first drill bit and the second drill bit is 5.9 mil.

9. The method of claim 1, wherein a diameter of the second drill bit is 9.8 mil.

10. The method of claim 1, further comprising:
drilling adjacent vias on the printed circuit board by selecting at least one configuration from a group including:
the first cylindrical drill hole of the via facing a first cylindrical drill hole of an adjacent via;
the first cylindrical drill hole of the via and the first cylindrical drill hole of the adjacent via on opposite sides of respective second cylindrical drill holes of the via and the adjacent via; and
the first cylindrical drill hole of the via and the first cylindrical drill hole of the adjacent via on same sides of the respective second cylindrical drill holes of the via and the adjacent via.

11. An apparatus comprising:
a substrate with one or more layers; and
a double-drilled via created on the substrate through the one or more layers, wherein the double-drilled via, comprises:
a first cylindrical drill hole that includes a first diameter and a first central axis, wherein the first cylindrical drill hole is drilled up to a first predetermined depth in the substrate using a first drill bit; and
a second cylindrical drill hole that includes a second diameter and a second central axis, wherein the second cylindrical drill hole is drilled up to a second predetermined depth in the substrate using a second drill bit, and wherein the second cylindrical drill hole overlaps with the first cylindrical drill hole such that the second central axis is offset from the first central axis.

12. The apparatus of claim 11, wherein the first cylindrical drill hole includes a drill slot.

13. The apparatus of claim 11, wherein the double-drilled via comprises one or more copper plates along an inner surface of the double-drilled via.

14. The apparatus of claim 13, wherein the double-drilled via is filled with epoxy.

15. The apparatus of claim 11, wherein the double-drilled via comprises a third cylindrical drill hole drilled from a bottom side of the substrate, wherein the third cylindrical drill hole includes a third central axis that is same as the second central axis of the second cylindrical drill hole.

16. The apparatus of claim 11, wherein the first diameter of the first cylindrical drill hole is smaller than or equal to the second diameter of the second cylindrical drill hole.

17. The apparatus of claim 11, further comprising a second double-drilled via created adjacent to the double-drilled via on the substrate, wherein the double-drilled via and the second double-drilled via have at least one configuration selected from a group including:
a first cylindrical drill hole of the second double-drilled via facing the first cylindrical drill hole of the double-drilled via;
the first cylindrical drill hole of the second double-drilled via and the first cylindrical drill hole of the double-drilled via on opposite sides of respective second cylindrical drill holes of the second double-drilled via and the double-drilled via; and
the first cylindrical drill hole of the second double-drilled via and the first cylindrical drill hole of the double-drilled via on same sides of the respective second cylindrical drill holes of the second double-drilled via and the double-drilled via.

18. An apparatus comprising:
a printed circuit board (PCB) including one or more layers, the PCB having at least one ball grid array (BGA); and
a double-drilled via that is formed on the PCB through at least two of the one or more layers, wherein the double-drilled via comprises:
a first cylindrical drill hole having a first diameter and a first central axis, wherein the first cylindrical drill hole is drilled into the PCB up to a first predetermined depth; and
a second cylindrical drill hole having a second diameter and a second central axis, wherein the second cylindrical drill hole is drilled into the PCB up to a second predetermined depth, and wherein the second cylindrical drill hole intersects with the first cylindrical drill hole such that the second central axis is offset from the first central axis.

19. The apparatus of claim 18, wherein one or more copper plates are placed along an inner surface of the double-drilled via and the double-drilled via is filled with epoxy.

20. The apparatus of claim 18, wherein the double-drilled via comprises a third cylindrical drill hole drilled from a bottom side of the PCB, wherein the third cylindrical drill hole includes a third central axis that is coincident with the second central axis of the second cylindrical drill hole.
